(19) United States
(12) Patent Application Publication
(10) Pub. No.: US 2005/0232066 A1
(43) Pub. Date: Oct. 20, 2005

(54) Method for characterizing cells with consideration for bumped waveform and delay time calculation method for semiconductor integrated circuits using the same

(75) Inventors: Noriko Ishibashi, Osaka (JP); Naoki Amekawa, Tokyo (JP); Nobufusa Iwanishi, Osaka (JP)

Correspondence Address: MCDERMOTT WILL & EMERY LLP, 600 13TH STREET, N.W., WASHINGTON, DC, 20005-3096, US

(73) Assignee: Matsushita Electric Industrial Co., Ltd.

(21) Appl. No.: 11/108,696

(22) Filed: Apr. 19, 2005

(30) Foreign Application Priority Data
Apr. 19, 2004 (JP) 2004-123450

(51) Int. Cl. G11C 8/00

(52) U.S. Cl. 365/233

(57) ABSTRACT

An effective input terminal capacitance which is effectively equivalent to a cell in which a waveform distortion is caused due to the Miller effect and a drive load connected to the cell is calculated in advance, and the cell and the drive load are replaced by the calculated effective input terminal capacitance, while considering that the Miller effect is caused according to the size of the drive load driven by a delay time calculation subject circuit, such as a cell, or the like, and a distortion occurs in input and output waveforms of the delay time calculation subject circuit due to the Miller effect. Thereafter, a circuit simulation is carried out using the effective input terminal capacitance. A resultant effective input terminal capacitance value is characterized as a function of an input slope waveform and the drive load and converted to table data.

### CROSS-REFERENCES TO RELATED APPLICATION

This Non-provisional application claims priority under 35 U.S.C. §119(a) on Patent Application No. 2004-123450 filed in Japan on Apr. 19, 2004, the entire contents of which are hereby incorporated by reference.

### BACKGROUND OF THE INVENTION

The present invention relates to a method for characterizing the characteristics of cells subjected to a delay time calculation with consideration for a waveform distortion in a semiconductor integrated circuit, which is provided for the purpose of performing a circuit design with consideration for a waveform distortion. The present invention further relates to a delay time calculation method using the characterization method.

In a general cell characteristic characterization method used in the preparation of a library for gate-level delay time calculation, various values of the input transition value and drive load are assigned to a cell subjected to a characterization (characterization subject cell), and the output transition value which represents the slope of a waveform at an output terminal and the cell delay time are measured. The output transition value and the value of the cell delay time are formatted in a two-dimensional table of the input transition value and the drive load which are to be assigned to a cell, whereby the characteristics of the cell are characterized and converted to a library. FIG. 24 shows an example of a conventional library used for calculating the cell delay time. In FIG. 24, indices Tran1 to Tran5, which are indicated by reference numeral 1001, are the input transition values input to a cell, and indices Load1 to Load5, which are indicated by reference numeral 1002, are the drive loads connected to an output terminal of the cell. Values D11 to D55 are the delay times of the cell which are obtained when the respective input transition values and drive load values are assigned.

Referring to the two-dimensional table of the input transition value and drive load, which is shown in FIG. 24, to determine the delay time of each cell which corresponds to the actual input transition value of the cell and the actual drive load driven by each gate is a common procedure in the conventional techniques. In this case, the input transition value assigned to each gate is calculated with a delay time calculation tool with reference to the threshold of a transition measurement using the time when the voltage reaches the threshold value.

IEICE Technical Report (Shingakugiho) VLD98-137 discloses an example of the delay time calculation method which uses the two-dimensional delay time table. According to this method, in the first place, the capacitance driven by a cell is obtained as an effective capacitance and, thereafter, a library generated by a two-dimensional delay time table of the input transition value and the drive load is referred to determine a delay time which corresponds to the input transition value assigned to the cell and the value of the previously-obtained effective capacitance (drive load), whereby the delay time of the cell is calculated.

Japanese Unexamined Patent Publication No. 2001-67387 proposes another delay time calculation method, which is used when a waveform input to a cell has a distortion. In this method, a nonlinear signal waveform input to the cell is subjected to a linear approximation as a group of linear signal waveforms, and a result of the linear approximation is used to perform a delay time calculation.

In a post-layout circuit modification which uses the above-described conventional delay time calculation method, setup verification and hold verification are performed based on a result of the delay time calculation. A path which can cause a malfunction due to an early arrival of a signal is subjected to a delay time adjustment process by means of buffer insertion, or the like. As for a path which can causes a malfunction due to a late arrival of a signal, the driving capacity of a cell in the path is increased, for example.

However, there is a possibility that distortion occurs in a signal waveform input to/output from each cell according to the relationship between the driving capacity of the cell and the drive capacitance. Nevertheless, the delay time calculation method described in IEICE Technical Report VLD98-137 fails to consider such a case and is based on the premise that no distortion occurs in the input waveform. Thus, the calculation result includes an error when waveform distortion occurs as described above.

Especially when waveform distortion occurs in the vicinity of the threshold of delay measurement due to the above-described reason, a cell characteristic extraction result greatly differs from an actual result, and accordingly, the accuracy of delay time calculation deteriorates.

In the delay time calculation method described in Japanese Unexamined Patent Publication No. 2001-67387, distortion in the waveform input to a cell is considered for improving the calculation accuracy, but the influence of distortion in the waveform which occurs depending on the size of the capacitance driven by the cell is not considered. Therefore, when distortion occurs due to such a reason, the calculation result includes an error.

Further, also when the above conventional delay time calculation methods are used in a post-layout circuit modification, distortion occurs in the waveform input to/output from a cell in actuality, and therefore, the actual delay time can be longer than calculated. In such a case, for example, an additional effort of modifying a circuit is required in a hold error correction process. Further, the above calculation error can result in missing an error in a setup error correction process.

### SUMMARY OF THE INVENTION

An objective of the present invention is to realize an accurate delay time calculation with consideration for a cause of distortion which occurs in a waveform input to/output from a circuit that is subjected to delay time calculation due to the size of the drive load driven by a cell and the slope waveform input to the cell.

In order to achieve the above objective, according to the present invention, specific circuit conditions obtained when an input/output waveform includes distortion are extracted as parameters for a slope waveform input to a delay time calculation subject circuit and the drive load which is driven by the delay time calculation subject circuit. Further, the relationship of these parameters is converted to a library. The library is referred to in an actual delay time calculation, whereby a correct output waveform and a delay value are calculated from the input slope waveform and the drive load. The library is also referred to when a post-layout circuit modification is performed, whereby the influence of waveform distortion is considered.

One aspect of the present invention is directed to a cell characteristic characterization method for characterizing the characteristics of a cell to which a predetermined drive load is connected, where an input waveform to the cell has a distortion due to the Miller effect, the method comprising: an effective input terminal capacitance calculation step of calculating an effective input terminal capacitance of the cell which corresponds to a case where the input waveform input to the characterization subject cell to which the drive load is connected results in a distorted waveform which is delayed from the input waveform by a predetermined delay time due to the Miller effect; and a storage step of storing the effective input terminal capacitance calculated at the effective input terminal capacitance calculation step as a function of the input waveform and the value of the drive load.

Another aspect of the present invention is directed to a cell characteristic characterization method, comprising: an input slope waveform generation step of generating an input slope waveform; an input bump waveform generation step of generating an input bump waveform; a circuit simulation step of inputting an input waveform which includes the input slope waveform and the input bump waveform superimposed thereon to the characterization subject cell and measuring an output waveform of the characterization subject cell which corresponds to the input waveform input to the characterization subject cell; a slope waveform/bump waveform separation step of separating the measured output waveform of the characterization subject cell into an output slope waveform and an output bump waveform; and a storage step of storing the output slope waveform and the output bump waveform as a function of the input slope waveform and the input bump waveform.

In one embodiment of the present invention, each of the input bump waveform and the output bump waveform is defined by a waveform transition time of the slope waveform, a bump waveform height, a bump waveform width, a bump area, a time interval which elapses till the bump waveform reaches a peak, and a timing at which the bump waveform is superimposed on the slope waveform.

Still another aspect of the present invention is directed to a cell characteristic characterization method for characterizing a characterization subject cell to which a predetermined drive load is connected, a cell which has a small driving capacity being connected to an input side of the characterization subject cell, the method comprising: a waveform distortion detection step which includes inputting an input waveform to the small driving capacity cell, and detecting the presence/absence of a waveform distortion in an input waveform and an output waveform of the characterization subject cell as a result of the input waveform to the small driving capacity cell; and a storage step of storing the presence/absence of the waveform distortion in the input waveform and the output waveform of the characterization subject cell as a function or table of the input waveform of the characterization subject cell and the value of the drive load.

Still another aspect of the present invention is directed to a delay time calculation method for calculating a delay time of a semiconductor integrated circuit with consideration for a waveform distortion using the above-described cell characteristic characterization method, the semiconductor integrated circuit including a plurality of cells connected by a plurality of lines, the method comprising: a drive load/input waveform extraction step of extracting an input waveform and a value of a drive load as to a delay time calculation subject cell selected from the plurality of cells; a distortion-generating pattern determination step of referring to the function of the above-described cell characteristic characterization method to determine whether or not a pattern of the delay time calculation subject cell which corresponds to the extracted input waveform and the extracted value of the drive load generates a distortion in the input waveform or the output waveform; if the pattern is not determined to be a pattern which generates a distortion at the distortion-generating pattern determination step, a gate-level delay time calculation step of performing a gate-level delay time calculation process on the delay time calculation subject cell; and if the pattern is determined to be a pattern which generates a distortion at the distortion-generating pattern determination step, a transistor-level delay time calculation step of performing a transistor-level delay time calculation process on the delay time calculation subject cell.

In one embodiment of the present invention, the delay time calculation method further comprises a waveform distortion detection step, which includes detecting whether or not a waveform distortion occurs in an input waveform and an output waveform of the delay time calculation subject cell after the delay time calculation at the transistor-level delay time calculation step, and if a waveform distortion occurs, repeating a transistor-level delay time calculation at the transistor-level delay time calculation step till the occurrence of the waveform distortion is stopped.

Still another aspect of the present invention is directed to a delay time calculation method for calculating a delay time of a semiconductor integrated circuit with consideration for a waveform distortion, the semiconductor integrated circuit including a plurality of instances connected by a plurality of nets, the method comprising: a first delay time calculation step of calculating a delay time of all the instances and a line delay time of all the nets and signal waveforms at input and output terminals of all the instances; an instance input signal waveform calculation step of obtaining a distorted input signal waveform which is distorted due to the Miller effect of a delay time calculation subject instance selected from the plurality of instances, the instance input signal waveform calculation step including inputting a variable input terminal capacitance value of the delay time calculation subject instance which is determined according to the presence/absence of a distortion caused by the Miller effect in an input waveform, representing the variable input terminal capacitance value as a coupling capacitance between input and output terminals of the delay time calculation subject instance, and calculating crosstalk using a net connected to the output terminal of the delay time calculation subject instance as an aggressor and a net connected to the input terminal of the delay time calculation subject instance as a victim; an instance output signal waveform transfer step of obtaining a distorted output signal waveform of the delay time calculation subject instance, the instance output signal waveform transfer step including inputting the distorted input signal waveform calculated at the instance input signal waveform calculation step, and calculating a signal waveform transfer between the input and output terminals of the delay time calculation subject instance; and a second delay time calculation step which includes calculating a delay time of the delay time calculation subject instance based on the distorted input signal waveform and the distorted output signal waveform of the delay time calculation subject instance, and allowing transfer of the distorted output signal waveform to calculate a delay time of a subsequent instance and a line delay time of a subsequent net.

Still another aspect of the present invention is directed to a delay time calculation method for calculating a delay time of a semiconductor integrated circuit with consideration for a waveform distortion, the semiconductor integrated circuit including a plurality of instances connected by a plurality of nets, the method comprising: a first delay time calculation step of calculating a delay time of all the instances and a line delay time of all the nets and signal waveforms at input and output terminals of all the instances; an instance input signal waveform calculation step of obtaining a distorted input signal waveform which is distorted due to the Miller effect of a delay time calculation subject instance selected from the plurality of instances, the instance input signal waveform calculation step including inputting a variable input terminal capacitance value of the delay time calculation subject instance which is determined according to the presence/absence of a distortion caused by the Miller effect in an input waveform, representing the variable input terminal capacitance value as a coupling capacitance between input and output terminals of the delay time calculation subject instance, and calculating crosstalk using a net connected to the output terminal of the delay time calculation subject instance as an aggressor and a net connected to the input terminal of the delay time calculation subject instance as a victim; an instance output signal waveform calculation step of obtaining a distorted output signal waveform which is distorted due to the Miller effect of the delay time calculation subject instance, the instance output signal waveform calculation step including inputting the variable input terminal capacitance value, representing the variable input terminal capacitance value as a coupling capacitance between the input and output terminals of the delay time calculation subject instance, and calculating crosstalk using a net connected to the input terminal of the delay time calculation subject instance as an aggressor and a net connected to the output terminal of the delay time calculation subject instance as a victim; a second delay time calculation step which includes calculating a delay time of the delay time calculation subject instance based on the distorted input signal waveform and the distorted output signal waveform of the delay time calculation subject instance, and allowing transfer of the distorted output signal waveform to calculate a delay time of a subsequent instance and a line delay time of a subsequent net.

Still another aspect of the present invention is directed to a delay time calculation method for calculating a delay time of a semiconductor integrated circuit with consideration for a waveform distortion using the above-described cell characteristic characterization method, the semiconductor integrated circuit including a plurality of instances connected by a plurality of nets, the method comprising: a slope waveform/bump waveform separation step of separating an input waveform including an superposed input bump waveform, which is input to a delay time calculation subject instance selected from the plurality of instances, into an input slope waveform on which the input bump waveform is not superimposed and the input bump waveform; a library reference step of referring to the function of the above-described cell characteristic characterization method to obtain an output slope waveform and an output bump waveform of the delay time calculation subject instance which correspond to the input slope waveform and the input bump waveform and obtain as an output waveform of the delay time calculation subject instance an output waveform formed by the output slope waveform and the output bump waveform superimposed thereon; and if a bump waveform occurs due to an external factor in a subsequent net connected to an output side of the delay time calculation subject instance, a net waveform calculation step of inputting information of the bump waveform and superimposing the bump waveform on an output waveform of the delay time calculation subject instance to calculate an output waveform of the subsequent net.

Still another aspect of the present invention is directed to an input waveform calculation method for calculating a distorted input signal waveform of a cell which is distorted due to the Miller effect using the above-described cell characteristic characterization method, an input side of the cell being connected to a line, an output side of the cell being connected to a drive load, the method comprising: an input terminal capacitance calculation step of referring to the function of the above-described cell characteristic characterization method to calculate an effective input terminal capacitance which corresponds to an input waveform of the waveform calculation subject cell which is obtained before the distortion and a value of the drive load; and a waveform calculation step of calculating an input waveform of the waveform calculation subject cell which is obtained after the distortion based on an output signal waveform of the line connected to the input side of the input waveform calculation subject cell and a load capacitance obtained by adding the capacitance of the line connected to the input side of the waveform calculation subject cell to the calculated effective input terminal capacitance.

Still another aspect of the present invention is directed to a delay time calculation method for calculating a delay time of a semiconductor integrated circuit with consideration for a waveform distortion, the semiconductor integrated circuit including a plurality of instances connected by a plurality of nets, the method comprising: a delay time calculation step which includes calculating a delay time of all the instances and a line delay time of all the nets, signal waveforms at input and output terminals of all the instances, and an effective input terminal capacitance of all the instances, inputting a Miller effect-causing condition which includes an input signal waveform and an effective input terminal capacitance, collating the input signal waveform and the effective input terminal capacitance calculated for each instance with the Miller effect-causing condition, listing an instance in which the Miller effect is caused in an input signal to output the list as a Miller effect-caused instance list; a static timing analysis step which includes assigning the delay time calculated at the delay time calculation step to a netlist to perform a static timing analysis, determining whether or not a timing of each path satisfies a timing design specification, if the timing design specification is not satisfied, storing a difference between a timing of the unsatisfactory path and the timing design specification as slack information; a Miller effect-caused instance extraction step which includes collating an instance included in a path which is determined not to satisfy the timing design specification at the static timing analysis step with the Miller effect-caused instance list, if the instance included in the path is included in the Miller effect-caused instance list, calculating a delay variation caused due to the Miller effect of the instance to output the calculated delay variation as a path delay variation report; and a timing redetermination step which includes collating the slack information of the path which is determined not to satisfy the timing design specification with the path delay variation report, and if the timing design specification is satisfied with the delay variation caused due to the Miller effect, redetermining that the path satisfies the timing design specification.

Still another aspect of the present invention is directed to a delay time calculation method for calculating a delay time of a semiconductor integrated circuit with consideration for a waveform distortion, the semiconductor integrated circuit including a plurality of instances connected by a plurality of nets, the method comprising: a static timing analysis step which includes inputting a netlist, a delay time of the plurality of instances, and a line delay time of the plurality of nets, and assigning the delay time and the line delay time to the netlist to perform a static timing analysis; a timing MET determination step of determining whether or not a result of the timing analysis at the static timing analysis step satisfies a timing design specification; if it is determined at the timing MET determination step that the timing design specification is not satisfied, a circuit modification step of performing a circuit modification including change of the instance size or rearrangement of lines based on layout information for timing correction; a delay time calculation step which includes calculating a delay time of all the instances and a line delay time of all the nets after the circuit modification of the circuit modification step, and after the calculation, returning to the static timing analysis step; if it is determined at the timing MET determination step that the timing design specification is satisfied, a Miller effect-caused instance extraction step of extracting an instance included in a path in which the Miller effect occurs based on a Miller effect-causing condition but the timing fails to satisfy the timing design specification as a result of the occurrence of the Miller effect; and a circuit modification method determination step which includes determining a circuit modification method from a method for modifying the Miller effect-caused instance extracted at the Miller effect-caused instance extraction step and a method for modifying an instance which is a factor that causes the Miller effect, and returning to the circuit modification step.

In one embodiment of the present invention, the circuit modification method determination step includes: a Miller effect-caused instance modification method presentation step of presenting a circuit modification method for changing a cell size of an instance in which the Miller effect is caused to a cell size such that the Miller effect is removed; a Miller effect-causing factor instance modification method presentation step of presenting a circuit modification method for changing a cell size of an instance which generates a signal waveform that causes the Miller effect to a cell size such that the Miller effect is removed; and an optimum modification method selection step of comparing the two circuit modification methods presented at the two modification method presentation steps to select therefrom a circuit modification method which causes minimum area damage.

With the above features of the present invention, an effective input terminal capacitance which is a load replaceable with and effectively equivalent to a cell and a drive load and which represents a load corresponding to a case where a waveform distortion is caused due to the Miller effect is calculated according to the cell characteristics, and the calculated effective input terminal capacitance is characterized while being associated with an input waveform and the drive load.

According to the present invention, an input slope waveform and an input bump waveform are generated, and the input bump waveform is superimposed on the input slope waveform to obtain a bump-superimposed input slope waveform. Then, an output waveform derived from the bump-superimposed input slope waveform is separated into an output slope waveform and an output bump waveform. The input and output bump waveforms are defined by parameters which are represented by a waveform transition time, a bump waveform height, a bump waveform width, a bump area, a time interval which elapses till the bump reaches a peak, and a timing at which the bump waveform is superimposed on the waveform. The input and output slope waveforms on which the input and output bump waveforms are superimposed are associated with the input slope waveform on which the bump waveform is not superimposed and the drive load corresponding to a case where the bump occurs, whereby the cell characteristics are characterized.

According to the present invention, a cell having a small driving capacity is connected to the input side of a cell characteristics characterization subject cell. With such a feature, an input waveform distortion of the cell characteristics characterization subject cell is acutely sensed. The condition which causes a waveform distortion is converted into a two-dimensional table of the input transition value of an input slope waveform in which a distortion is not caused and a drive load capacitance value corresponding to a case where a distortion is caused, whereby the cell characteristics are characterized, and a result thereof is converted to a library.

According to the present invention, the drive load capacitance driven by a cell and the input transition value to the cell are detected, and a library is referred to as to the detected parameters to extract a pattern which generates a distortion in a waveform based on the drive load capacitance value and the input transition value. If a distortion-generating pattern is not extracted, a gate-level delay time calculation is performed, whereby the process time is shortened. If a distortion-generating pattern is extracted, a transistor-level delay time calculation is performed. In the transistor-level delay time calculation, it is detected whether or not a distortion is caused in an output waveform. After a distortion is not caused in the output waveform, another delay time calculation subject is then processed.

According to the present invention, the delay time of all the instances and lines in a design and the signal waveforms at input and output terminals are calculated based on a delay library and RC information. The variable capacitance value is represented as a coupling capacitance between the input and output terminals of a cell, whereby the Miller effect is considered. In addition to a variation of the input waveform due to the Miller effect, a crosstalk calculation is performed with a net connected to the output terminal of an instance as an aggressor and a net connected to the input terminal of the instance as a victim, whereby a signal waveform transfer between the input and output terminals of the instance is calculated, and an instance output signal waveform is calculated with consideration for the Miller effect. Then, a delay time of a cell is calculated from the thus-obtained instance input signal waveform and instance output signal waveform. Further, each of the signal waveforms is allowed to transfer, and the line delay and the delay time of other cells are calculated. In this way, a variation of a signal waveform and a delay time variation due to the Miller effect can be calculated.

According to the present invention, also in obtaining an output waveform of the instance, an output waveform of an instance is calculated with consideration for the Miller effect from the variable capacitance value due to the Miller effect and the waveforms at the input and output terminals as in obtaining the input waveform. Furthermore, a crosstalk calculation is performed with a net connected to the instance input terminal as an aggressor and a net connected to the instance output terminal as a victim, whereby a variation of an instance output signal waveform is calculated with consideration for the Miller effect and the crosstalk.

According to the present invention, a net waveform is separated into a bump waveform and a net input slope waveform, and the obtained library is referred to to obtain a net output waveform including a superimposed bump waveform. If a bump waveform is caused due to an external factor, such as crosstalk, simultaneous transition noise, overshoot or undershoot due to inductance, or the like, the bump waveform caused due to such an external factor is also superimposed on the net waveform to obtain a net output waveform.

According to the present invention, a circuit portion which includes a net subsequent to an instance subjected to a delay time calculation (delay time calculation subject instance) and the input terminal capacitance of an instance subsequent to the net that is subsequent to the delay time calculation subject instance falls back into an effective drive load of the delay time calculation subject instance. The library obtained by the delay time calculation subject circuit characterization method is referred to as to the drive load and the input terminal capacitance of the instance in which the Miller effect is not caused to obtain an equivalent input terminal capacitance. Further, the library is referred to to obtain an effective input terminal capacitance which replaces the equivalent input terminal capacitance and the drive load. Then, a waveform calculation is performed using the effective input terminal capacitance, whereby the cell delay and the cell output slew rate are calculated.

According to the present invention, a list of instances in which the Miller effect is caused is prepared based on the input waveform and the drive load capacitance to be driven, along with the delay time calculation of all the instances and the line delay time calculation. As for a path which fails to satisfy a static timing, an instance in which the Miller effect is caused is extracted from the instances of the list. Herein, the timing redetermination is performed with consideration for the static timing and the delay caused by the Miller effect.

Further, according to the present invention, if the timing specification is not satisfied as a result of a static timing analysis, the delay time calculation process of the present invention proceeds to a circuit modification step. If the timing specification is satisfied, the presence/absence of occurrence of the Miller effect is verified. At this step, if the Miller effect does not occur, the delay time calculation is terminated. If the timing specification is not satisfied due to occurrence of the Miller effect, a circuit modification method is determined, and the delay time calculation process of the present invention proceeds to the circuit modification step. After the circuit modification step, a delay time calculation is carried out to perform a static timing analysis again.

According to the present invention, in the determination of a circuit modification method in the delay time calculation method, a method for modifying an instance in which the Miller effect occurs and a method for modifying an instance which influences occurrence of the Miller effect are compared, and one of the methods which causes the minimum area damage is selected.

### BRIEF DESCRIPTION OF THE DRAWINGS

FIG. 1 is a flowchart of a variable input terminal capacitance characterization method according to embodiment 1 of the present invention.

FIG. 2A shows a variable input terminal capacitance characterization subject circuit according to embodiment 1 of the present invention. FIG. 2B shows a circuit in which a cell and a drive load are replaced by an effective input terminal capacitance.

FIG. 3 shows cell input voltage waveforms in an example of variable input terminal capacitance characterization method according to embodiment 1 of the present invention.

FIG. 4 is a flowchart of a bump-superimposed waveform characterization method according to embodiment 2 of the present invention.

FIG. 5 shows a bump-superimposed waveform characterization subject circuit according to embodiment 2 of the present invention.

FIG. 6 illustrates an example of bump-superimposed waveform characterization according to embodiment 2 of the present invention.

FIG. 7 shows a circuit with which the condition of causing a bump is characterized according to embodiment 3 of the present invention.

FIG. 8 is a flowchart of a process of characterizing the condition which causes a bump waveform according to embodiment 3 of the present invention.

FIG. 9 shows an example of a library which describes the presence/absence of a bump waveform occurs according to embodiment 3 of the present invention.

FIG. 10 is a flowchart of a delay time calculation process for a case where a bump occurs in a waveform according to embodiment 4 of the present invention.

FIG. 11 is a flowchart of a delay time calculation process in which a delay variation caused by the Miller effect is considered according to embodiment 5 of the present invention.

FIG. 12A shows a circuit subjected to a delay time calculation process according to embodiment 5 of the present invention. FIG. 12B shows the waveforms at respective points in the circuit of FIG. 12A which correspond to the steps of the process flow shown in FIG. 11.

FIG. 13 is a flowchart of a delay time calculation process in which a delay variation caused by the Miller effect is considered according to embodiment 6 of the present invention.

FIGS. 14A and 14B specifically illustrate the process flow of FIG. 13B according to embodiment 6 of the present invention.

FIG. 15 is a flowchart of a delay time calculation method in which a bump-superimposed waveform is considered according to embodiment 7 of the present invention.

FIG. 16A shows an example of a network subjected to the delay time calculation process in which a bump-superimposed waveform is considered according to embodiment 7 of the present invention. FIG. 16B shows the waveforms at respective points in the network of FIG. 16A.

FIG. 17 is a flowchart of a delay time calculation method in which a variable input terminal capacitance is considered according to embodiment 8 of the present invention.

FIG. 18A shows an example of a network subjected to the delay time calculation process in which a variable input terminal capacitance is considered according to embodiment 8 of the present invention. FIG. 18B shows the waveforms at respective points in the network of FIG. 18A.

FIG. 19 illustrates a timing redetermination method for a case where, in a timing analysis according to embodiment 9 of the present invention, a path which fails to satisfy the timing includes an instance in which the Miller effect occurs.

FIG. 20A shows a circuit subjected to the process of FIG. 19 according to embodiment 9 of the present invention. FIG. 20B illustrates the relationship between the delay time and the hold time in the circuit of FIG. 20A.

FIG. 21 is a flowchart of a timing correction process in which the Miller effect is considered according to embodiment 10 of the present invention.

FIG. 22 illustrates the process of selecting an optimum circuit modification method according to embodiment 10 of the present invention.

FIG. 23 illustrates examples of the optimum circuit modification method according to embodiment 10 of the present invention.

FIG. 24 shows an example of a library used in a conventional delay time calculation.

### DESCRIPTION OF THE PREFERRED EMBODIMENTS

Hereinafter, preferred embodiments of the present invention are described with reference to the attached drawings.

### Embodiment 1

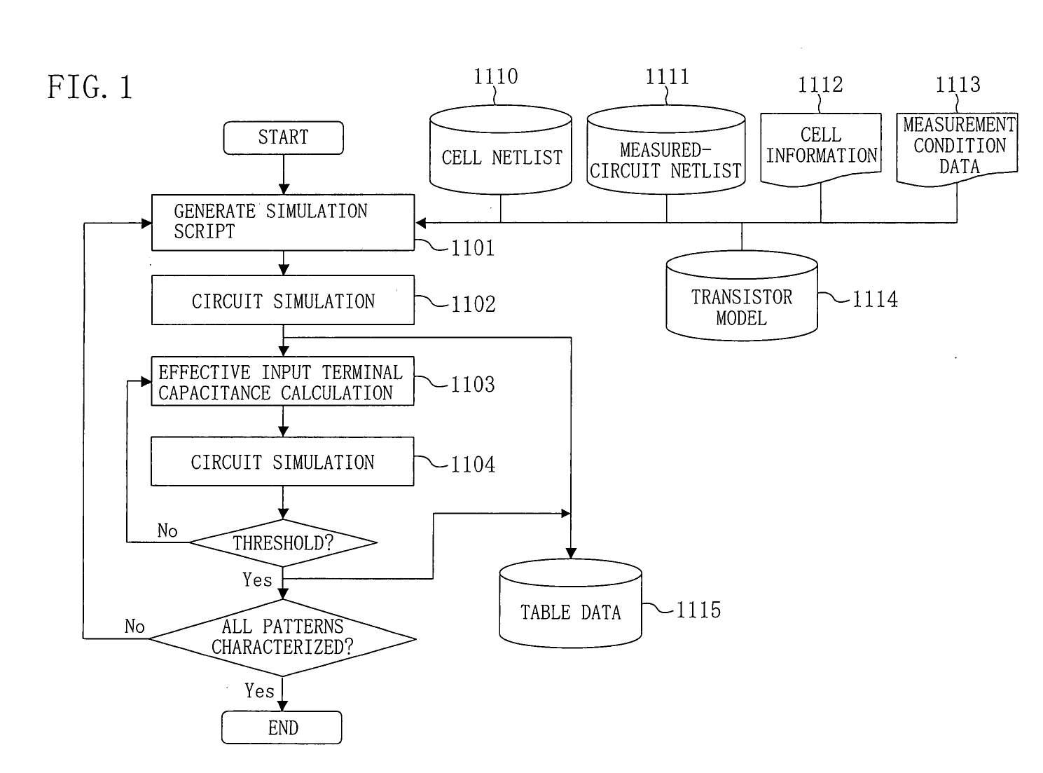

Embodiment 1 of the present invention is described with reference to FIGS. 1, 2 and 3.

FIG. 1 is a flowchart of a variable input terminal capacitance characterization method according to embodiment 1 of the present invention, in which a variation of the input terminal capacitance of a cell is considered. Embodiment 1 provides an example of a semiconductor integrated circuit formed by a large number of basic logic cells or function macroblocks (hereinafter, generically referred to as “cell(s)” for simplicity) which are connected by lines, and illustrates an example of delay time calculation with consideration for waveform distortion in each cell. In embodiment 1, a method for characterizing the characteristics of a cell is described on an assumption that waveform distortion is caused in the cell which is a delay time calculation subject circuit due to the Miller effect, and the waveform distortion causes a delay. It should be noted that, in the flowcharts of embodiment 1 and the subsequent embodiments, reference numerals attached to databases are also used for indicating data stored in the databases.

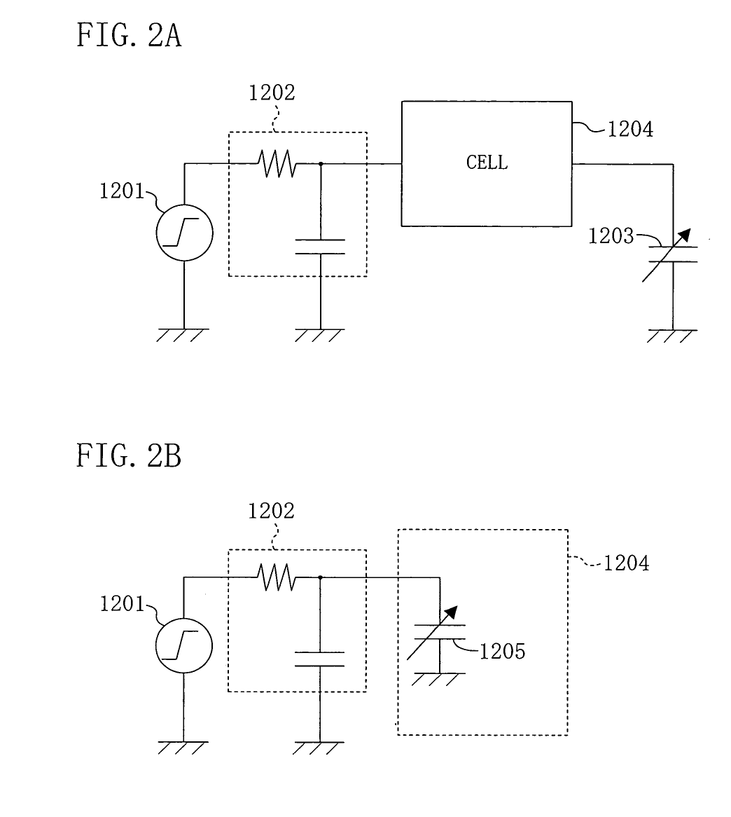

FIGS. 2A and 2B illustrate an example of characterization of the characteristics of a cell, which is a delay time calculation subject circuit, on the assumption that a waveform distortion is caused due to the Miller effect. In this example, the influence of the waveform distortion is modeled by the variation of the equivalent input terminal capacitance, and this model is used to carry out the characterization with high accuracy.

FIG. 2A shows a circuit with which characterization of a variable input terminal capacitance is described, wherein a waveform generated in a waveform generation circuit 1201 is input to a characterization subject cell (delay time calculation subject circuit) 1204 through a smoothing circuit 1202, which is formed by a resistance (R) and a capacitor (C), to drive a load section 1203. FIG. 2B illustrates that, in a delay time calculation, the characterization subject cell 1204 and the load section 1203 of FIG. 2A which are obtained when the Miller effect is caused are replaced by an effective input terminal capacitance 1205 which causes the same delay as that caused by the cell 1204 and load section 1203 when the Miller effect is caused.

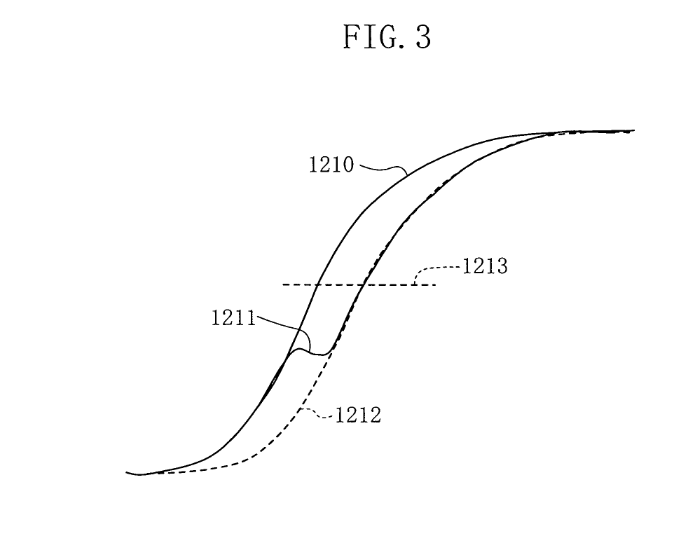

Herein, in the process of calculating the effective input terminal capacitance 1205, the equivalent input terminal capacitance is first calculated, and then, the effective input terminal capacitance 1205 is calculated using the equivalent input terminal capacitance. Specifically, in the case where the load section 1203 of FIG. 2A is a load which causes the Miller effect (first drive load) and an input waveform 1210 of FIG. 3 is deformed into an input waveform 1211 so that the Miller effect is caused, a certain delay time occurs at a drive point (drive voltage level) 1213 between the waveforms 1210 and 1211. The equivalent input terminal capacitance which is added at the input terminal of the characterization subject cell 1204 is calculated with consideration for the delay time between the waveforms 1210 and 1211. Specifically, the equivalent input terminal capacitance is calculated such that the waveform input to the characterization subject cell 1204 is a waveform 1212 as shown in FIG. 3 which corresponds to a case where the load section 1203 is a load which does not cause the Miller effect (second drive load), i.e., such that the waveform input to the characterization subject cell 1204 results in a waveform which has a delay time equal to the delay time of the waveform 1211 from the waveform 1210 at the drive point 1213. Thereafter, the effective input terminal capacitance 1205, which is the total of the calculated equivalent input terminal capacitance, the capacitance of the characterization subject cell 1204, and the load section 1203 which does not cause the Miller effect, is calculated.

Herein, the process flow of FIG. 1 is described with reference to FIGS. 2 and 3.

In FIG. 1, at the simulation script generation step 1101, a simulation script is generated based on a cell netlist 1110, a measured-circuit netlist 1111, cell information 1112, measurement condition data 1113, and transistor model information 1114. The cell netlist 1110 is circuit connection information which includes parasitic element information of a characterization subject cell 1204 of FIG. 2A. The measured-circuit netlist 1111 is connection information of a circuit of FIG. 2A which is subjected to characterization of a variable input terminal capacitance. The cell information 1112 is circuit simulation pattern information which describes the type, pin information, characteristics to be measured, etc., of a characterization subject cell which is a subject of measurement. The measurement condition data 1113 is an index of a load and input slew rate. The transistor model information 1114 is used in a circuit simulation.

At the circuit simulation step 1102, a circuit simulation is carried out based on the simulation script generated at step 1101. It should be noted that, as for the input waveform of this circuit simulation, the input slew rate value is changed by adjusting the parameters of the waveform generation circuit 1201 and the smoothing circuit 1202 shown in FIGS. 2A and 2B. Herein, the smoothing circuit 1202 shown in FIGS. 2A and 2B is a T-type circuit formed by a resistor and a capacitor. However, the smoothing circuit 1202 may be formed only by a capacitor or only by a resistor. Alternatively, the smoothing circuit 1202 may be a π-type circuit formed by a resistor and a capacitor. In the example of FIG. 2A, the drive load 1203 is formed only by a capacitor. However, the drive load 1203 may be a π-type circuit formed by a resistor and a capacitor.

At the effective input terminal capacitance calculation step 1103, when the waveform input to the characterization subject cell 1204 is not the waveform 1210 which is free from the Miller effect but the waveform 1211 which results from the Miller effect as shown in FIG. 3, the equivalent input terminal capacitance of the characterization subject cell 1204 is calculated such that the waveform 1212 free from the Miller effect, which overlaps the waveform 1211 at least at the drive point 1213, is obtained. Thereafter, the effective input terminal capacitance 1205, which is equivalent to the total of the equivalent input terminal capacitance, the capacitance of the characterization subject cell 1204, and the drive load 1203 which does not cause the Miller effect, is calculated.

At the circuit simulation step 1104, a circuit simulation is carried out using a circuit diagram shown in FIG. 2B wherein the effective input terminal capacitance 1205 is provided in substitution for the characterization subject cell 1204 to which the equivalent input terminal capacitance is added and the drive load 1203 of FIG. 2A.

As for the result of the circuit simulation at the circuit simulation step 1104, the delay at the drive point on the input waveform is compared with the delay of the waveform 1211 which results from the Miller effect. The series of steps 1103 and 1104 is repeated till the delay at the drive point becomes equal to or smaller than a predetermined threshold.

The effective input terminal capacitance 1205 calculated at step 1103 and the equivalent input terminal capacitance are recorded and stored in table data 1115 (storage step) as a function of the slew rate of the input waveform 1210 and the load section 1203 which are obtained when the Miller effect is not caused, together with the previously-obtained result of the circuit simulation step 1102.

The series of steps 1101 to 1104 is repeated till all of the patterns described in the measurement condition data 1113 are characterized.

It should be noted that, although only the rising edge is described herein, table data of the effective input terminal capacitance, the cell output slew rate value and the cell delay value is also generated as to a falling edge through the same process.

In the example of embodiment 1, the function is in the form of table data, but the present invention is not limited thereto. For example, the function may be represented by a polynomial.

As described above, according to embodiment 1, even when waveform distortion is caused due to the Miller effect, the influence of the waveform distortion is modeled by the variation of the equivalent input terminal capacitance, and the characteristics of a cell (delay time calculation subject circuit) can be characterized with high accuracy by using the model.

Further, logic synthesis can be carried out with the worst delay value by using the library described in embodiment 1. That is, return steps which occur after a layout process can be reduced.

### Embodiment 2

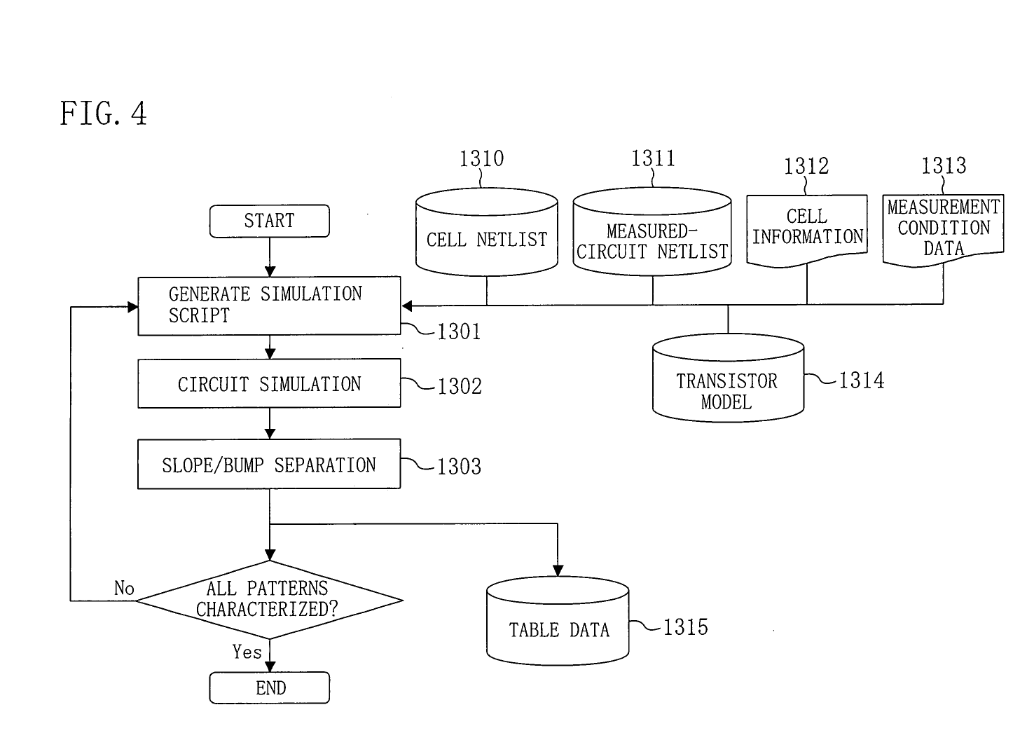

Next, embodiment 2 of the present invention is described with reference to FIGS. 4, 5 and 6.

FIG. 4 is a flowchart of a bump-superimposed waveform characterization method according to embodiment 2 of the present invention. In embodiment 2, a method for characterizing the characteristics of a cell based on the characteristics of a bump waveform which is a waveform component of the distortion is described on an assumption that waveform distortion is caused in a cell (delay time calculation subject circuit) due to the Miller effect, or the like, and the waveform distortion causes a delay.

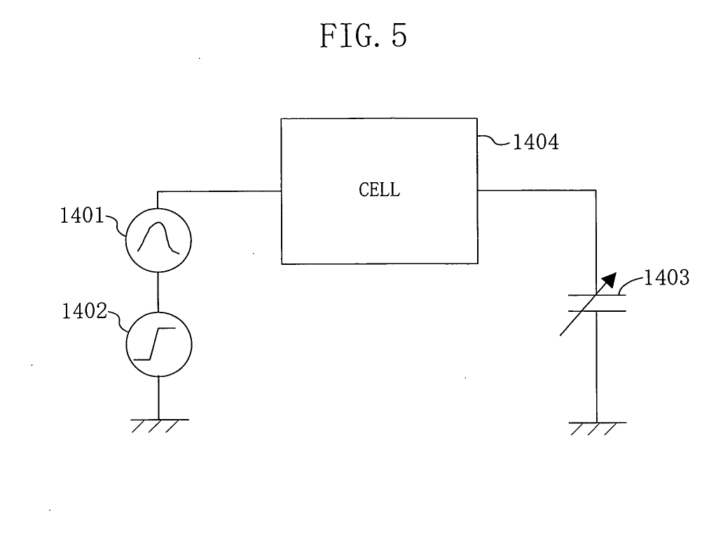

FIG. 5 shows a bump-superimposed waveform characterization circuit for generating an input waveform on which a bump is superimposed. The bump-superimposed waveform characterization circuit also measures the cell delay and the output waveform of a characterization subject cell 1404. In the example of FIG. 5, a bump (bump input waveform) generated by a bump voltage generation section 1401 is superimposed on a waveform (input slope waveform) generated by a waveform voltage generation section 1402, and the resultant waveform is input to a characterization subject cell 1404 to which a load 1403 is connected.

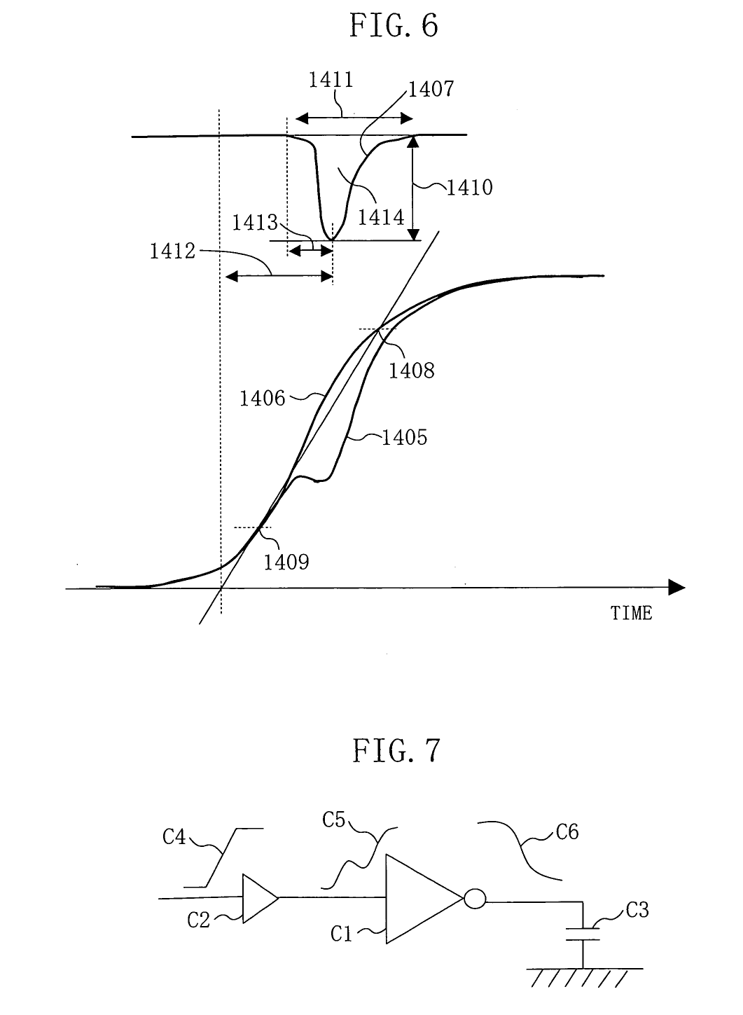

FIG. 6 shows a waveform 1405 which includes a superimposed bump, a slope waveform 1406 which is a waveform component of the waveform 1405, and a bump waveform 1407 on the same time axis. The bump waveform 1407 is represented by the bump height 1410, which is a peak value of the bump, the bump width 1411, and the bump area 1414. Further, the timing 1412 at which the bump is superimposed on the waveform, and the time interval 1413 that elapses till the bump reaches the peak are also shown. Herein, the timing 1412 at which the bump is superimposed on the slope waveform 1406 is defined, if it is a rising edge, by an interval from the time when a line including the upper slew trip point 1408 and the lower slew trip point 1409 of the slope waveform 1406 crosses the ground potential to the time when the bump reaches the peak value. If it is a falling edge, the timing 1412 is defined by an interval from the time when said line crosses the supply potential to the time when the bump reaches the peak value. The time interval 1413 that elapses till the bump waveform reaches the peak is the interval from the start of the bump to the time at which the bump waveform reaches the peak value.

Herein, the flowchart of FIG. 4 is described with reference to FIGS. 5 and 6.

In FIG. 4, at the simulation script generation step 1301, a simulation script is generated based on a cell netlist 1310, a measured-circuit netlist 1311, cell information 1312, measurement condition data 1313, and transistor model information 1314. The cell netlist 1310 is circuit connection information which includes parasitic element information of a characterization subject cell 1404 of FIG. 5A. The measured-circuit netlist 1311 is connection information of a variable input terminal capacitance characterizing circuit shown in FIG. 5. The cell information 1312 is circuit simulation pattern information that describes the type, pin information, characteristics to be measured, etc., of a cell which is a subject of measurement. The transistor model information 1314 is used in a circuit simulation. The measurement condition data 1313 includes the indices of the load and input slew rate of the slope waveform, the bump height 1410 and bump width 1411 of the bump waveform, the timing 1412 at which the bump is superimposed on the waveform, the time interval 1413 that elapses till the bump reaches the peak, and the index of the bump area 1414.

At the circuit simulation step 1302, a circuit simulation is carried out based on the simulation script generated at step 1301. Now, consider a case where the waveform on which the bump is superimposed as shown in FIG. 6 is input to the characterization subject cell 1404. The circuit simulation step 1302 includes an input bump waveform generation step of generating the input bump waveform 1407 by the bump voltage generation section 1401 of FIG. 5 and an input slope waveform generation step of generating the input slope waveform 1406 by the waveform voltage generation section 1402. The bump-superimposed waveform 1405 which is formed by the input bump waveform 1407 and the input slope waveform 1406 is an input waveform used in the circuit simulation. Through this simulation, the cell delay and output waveform of the characterization subject cell 1404 to which the load section 1403 is connected are calculated. The output waveform is measured as a waveform including a superimposed bump as is the input waveform. In the example of FIG. 5, the drive load is formed only by a capacitor. However, the drive load may be a π-type circuit formed by a resistor and a capacitor.

At the waveform/bump separation step 1303, assuming that the waveform shown in FIG. 6 is the output waveform, the output waveform 1405 including a superimposed bump is separated into the output slope waveform 1406 and the output bump waveform 1407.

As described above, the cell characteristics of the characterization subject cell 1404, i.e., the output waveform characteristics of the characterization subject cell 1404 which are obtained when the waveform 1405 defined by the input slope waveform 1406 and the bump waveform 1407 superimposed thereon as shown in FIG. 6 is input to the characterization subject cell 1404, are characterized as a function of the output slope waveform 1406 including no waveform distortion, the output bump waveform 1407 superimposed on the output slope waveform 1406, and the drive load of the load section 1403. The output bump waveform 1407 is equal to a difference between the output slope waveform 1406 which includes no waveform distortion and the output waveform 1405 which includes the output bump waveform 1407. The resultant function is recorded and stored in table data 1315 (storage step).

The series of steps 1301 to 1303 is repeated till all of the patterns described in the measurement condition data 1313 are characterized.

As described above, according to embodiment 2, a cell can be characterized even if a waveform of a non-monotonous increase or decrease has a distortion.

### Embodiment 3

Embodiment 3 of the present invention is described with reference to FIGS. 7, 8 and 9.

FIG. 7 is a circuit subjected to characterization for the purpose of verifying waveform distortion in a delay time calculation method in which waveform distortion is considered. In FIG. 7, the input terminal side of a characterization subject cell (delay time calculation subject circuit) C1 is connected to a cell C2 which has a small driving capacity. The output terminal side of the characterization subject cell C1 is connected to a load capacitor C3 which is driven by the characterization subject cell C1. The voltage input to the cell C2 of a small driving capacity has a waveform C4. The voltage input to the characterization subject cell C1 has a waveform C5. The voltage output from the characterization subject cell C1 has a waveform C6. In the circuit of FIG. 7, the cell C2 of a small driving capacity is connected to the input side of the characterization subject cell C1, and therefore, the input slope waveform C4, which has no distortion when it is input to the cell C2, has a distortion at the input terminal of the characterization subject cell C1, resulting in the slope C5 which includes the distortion.

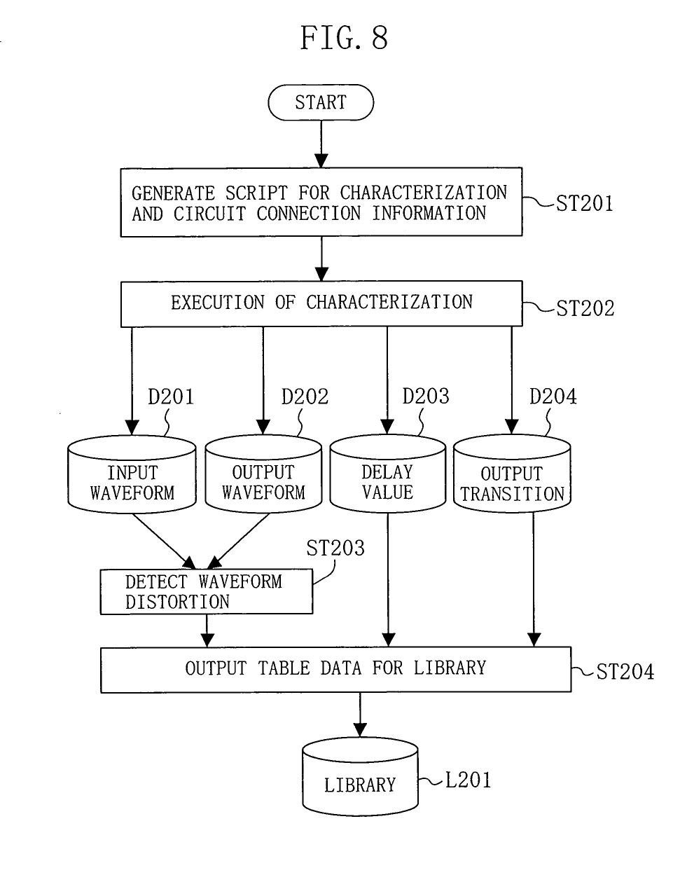

FIG. 8 is a flowchart for generating a library of the conditions under which distortion occurs in a waveform.

At step ST201 of FIG. 8, a script used in a characterization process and circuit connection information for characterization are generated.

At step ST202, the script and circuit connection information generated at step ST201 are read in, and cell characterization is carried out. Herein, the cell which is subjected to the characterization is the characterization subject cell C1 of FIG. 7.

As a result of the characterization at step ST202, an input waveform D201 is output as output data which corresponds to the waveform C5 input to the characterization subject cell C1 of FIG. 7, an output waveform D202 is output as output data derived from the waveform output from the characterization subject cell C1, and furthermore, a delay value D203 of the characterization subject cell C1 and an output transition D204 of the characterization subject cell C1 are output.

At the waveform distortion detection (waveform distortion observation) step ST203, a waveform distortion of the input/output waveforms of the characterization subject cell C1 is detected based on the input waveform D201 and the output waveform D202.

The three pieces of information obtained at steps ST202 and ST203, i.e., the presence/absence of waveform distortion, the delay value D203 of the characterization subject cell C1, and the output transition D204 of the characterization subject cell C1, are subjected to the process of the next step ST204. Specifically, at step ST204, a table in which the aforementioned three pieces of information (the presence/absence of waveform distortion, the delay value D203, and the output transition D204) are written with the input slope waveform C5 and drive load C3 of the characterization subject cell C1 as indices is prepared and stored as table data L201 for a library.

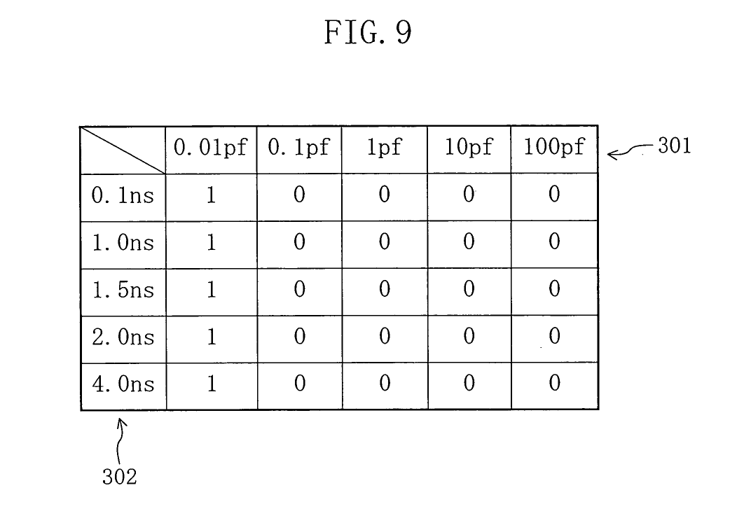

FIG. 9 shows an example of the table data L201 generated as the library table. In the table of FIG. 9, value “1” means that distortion occurs in both the waveforms input to and output from the characterization subject cell C1, and value “0” means that no distortion occurs in both the waveforms input to and output from the characterization subject cell C1. The transition 302 of the waveform input to the characterization subject cell C1 and the largeness 301 of the drive load are the indices of the table of FIG. 9. As seen from the example of the table of FIG. 9, when the drive load is 0.01 pf, distortion occurs in all of the waveforms irrespective of the input transition. It can be determined by using this table what load is driven by a cell when distortion occurs in a waveform.

It should be noted that, when waveform distortion is not detected, the delay value D203 and the output transition D204 which are obtained at step ST202 can be used for a general delay time calculation. Even when a waveform distortion is detected, the delay value D203 and the output transition D204 can be used as a delay value and slope obtained on the occurrence of a waveform distortion so long as the waveform distortion causes no influence on the measurement of the delay value and slope and is permissible in view of accuracy. However, in a delay time calculation carried out with high accuracy, the delay value D203 and the output transition D204 should not be used if they are obtained when a waveform distortion occurs.

### Embodiment 4

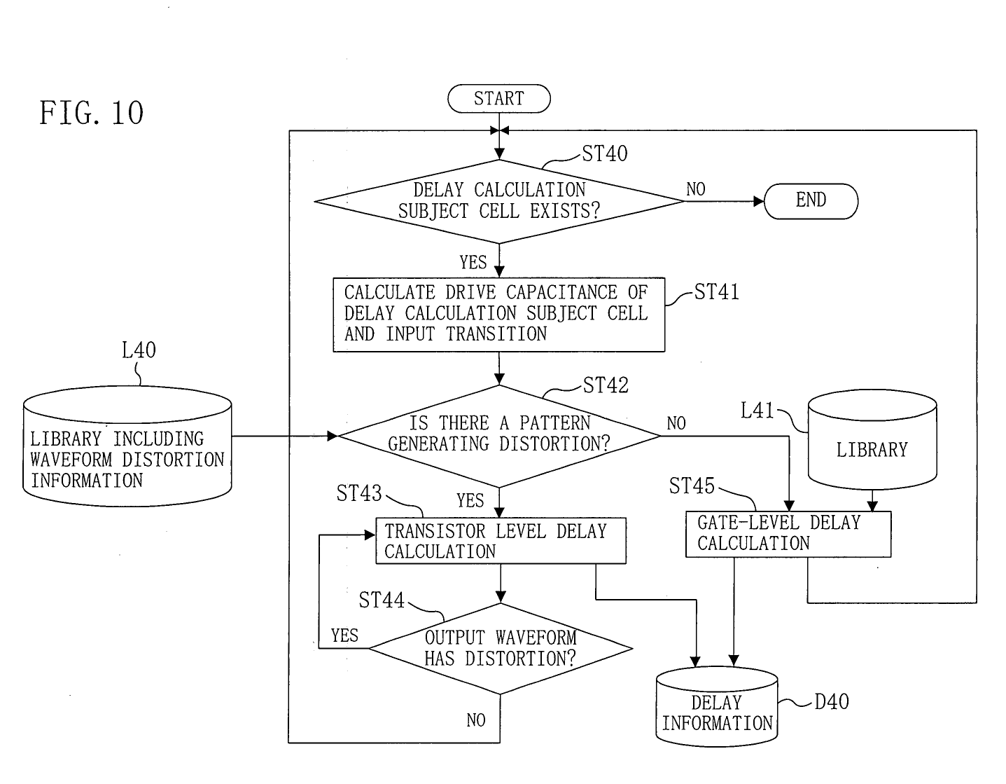

Embodiment 4 of the present invention is described with reference to FIG. 10.

FIG. 10 is a flowchart of a delay time calculation process in a delay time calculation method in which waveform distortion is considered.

In FIG. 10, at the delay time calculation subject identification step ST40, it is determined whether or not there is a cell which is to be subjected to the delay time calculation.

If there is a cell which is to be subjected to the delay time calculation (“YES” at step ST40), the input transition value and the drive load capacitance of the delay time calculation subject cell are calculated (drive load/input waveform extraction step ST41).

At the distortion-generating pattern detection step ST42, it is determined from the input transition value and drive load calculated at step ST41 whether or not there is a pattern of a cell which generates a distortion in the waveform. In the determination at step ST42, the library L201 in which one or more patterns that generate waveform distortion are registered (as obtained in embodiment 3) is referred to. (It should be noted that the library is shown as “library L40” in FIG. 10) If the pattern generates a distortion (“YES” at step ST42), a transistor-level delay time calculation is carried out (transistor-level delay time calculation step ST43). If the pattern generates no distortion (“NO” at step ST42), a gate-level delay time calculation is carried out (gate-level delay time calculation step ST45). A result of the transistor-level delay time calculation at step ST43 is stored in a database as delay information D40.

At the waveform distortion detection step ST44, the output waveform obtained as a result of the transistor-level delay time calculation at step ST43 is referred to. If the waveform has a distortion (“YES” at step ST44), the process returns to step ST43. At step ST43, the transistor-level delay time calculation is carried out again. If the waveform has no distortion (“NO” at step ST44), the process returns to step ST40. At step ST40, the delay time calculation is performed on another delay time calculation subject cell.

At step ST45, a gate-level delay time calculation is performed on a pattern which generates no distortion using a general library L41 which is written as the function of the transition value input to the cell and the drive load. The calculation result is stored as the delay information D40 in the database as is the result of the transistor-level delay time calculation of step ST43. Then, the process returns to step ST40, and a next delay time calculation subject cell is searched for.

### Embodiment 5

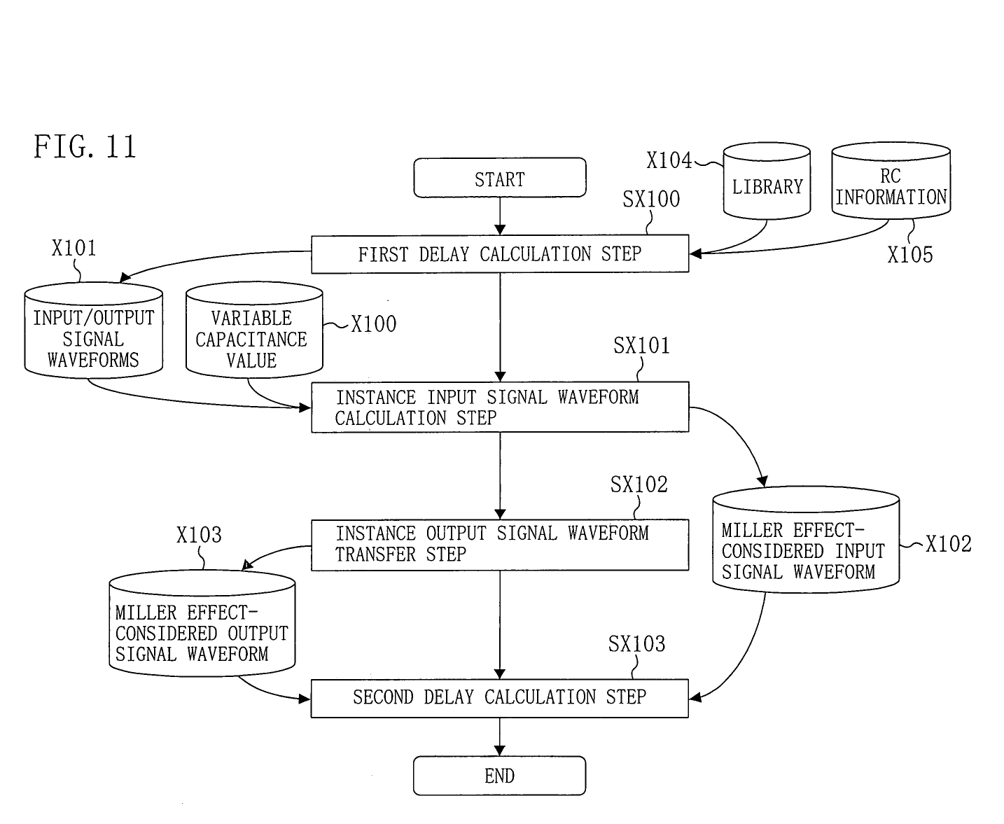

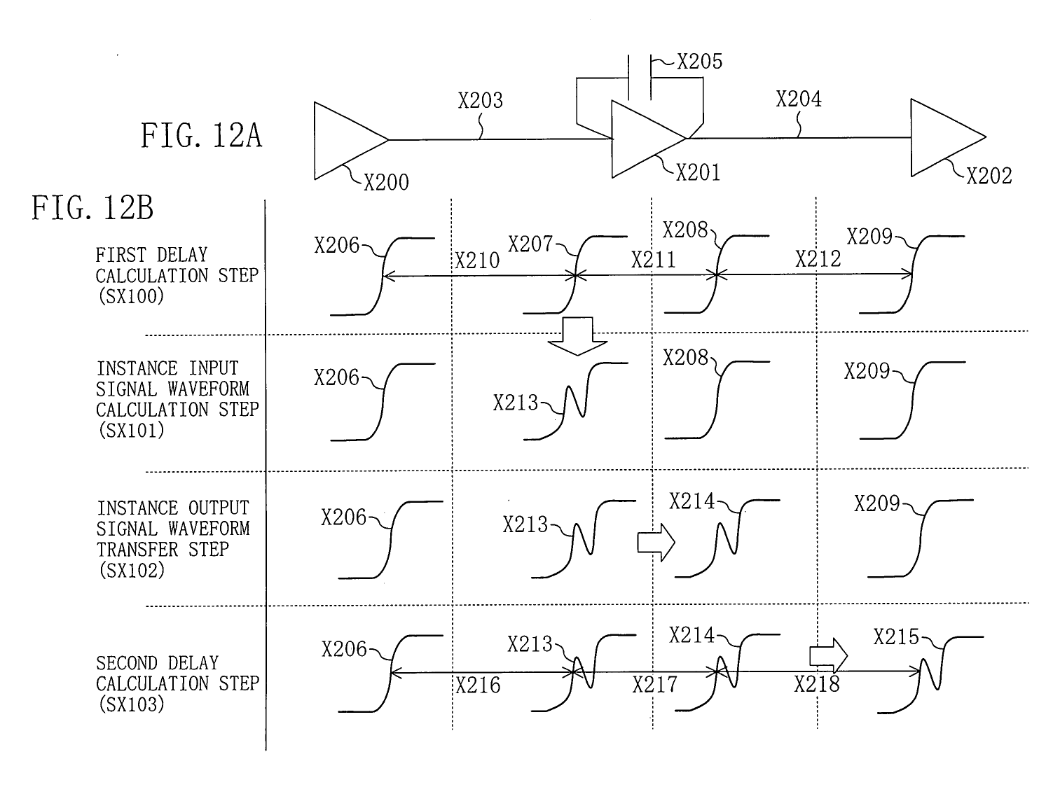

Embodiment 5 of the present invention is described with reference to FIGS. 11 and 12.

FIG. 11 is a flowchart of a delay time calculation process in which a delay variation caused due to the Miller effect is considered. FIG. 12A shows a specific example of a circuit subjected to the delay time calculation process. In the circuit of FIG. 12A, an instance X200 and an instance X201 are connected by a line X203, and the instance X201 and an instance X202 are connected by a line X204. A coupling capacitance X205 is connected between the input and output terminals of the instance X201 for consideration of the Miller effect on the instance X201. FIG. 12B shows the waveforms at the output terminal of the instance X200, the input and output terminals of the instance X201, and the input terminal of the instance X202 in the circuit of FIG. 12A, with the corresponding steps of the process flow of FIG. 11.

Herein, the flowchart of FIG. 11 is described with reference to FIGS. 12A and 12B.

In FIG. 11, at the first delay time calculation step SX100, the delay time of all the instances and the line delay time in a design are calculated based on a delay library X104 that describes the delay characteristic of each basic logic cell and RC information X105 that describes the resistance and capacitance value of the lines in a design process. At the same time, the input/output signal waveforms X101 at the input/output terminals of each cell are calculated. It should be noted that although, in the example of embodiment 5, the delay library X104 and the RC information X105 are read in at the first delay time calculation step SX100, a netlist of a design, setting of a boundary and/or timing restrictions may be additionally read in for delay time calculation.

In this calculation with the circuit structure shown in FIG. 12A, the Miller effect is not considered at step SX100 and, therefore, the coupling capacitance X205 is omitted. As a result, an output signal waveform X206 is obtained at the output terminal of the instance X200; an input signal waveform X207 is obtained at the input terminal of the instance X201; an output signal waveform X208 is obtained at the output terminal of the instance X201; and an input signal waveform X209 is obtained at the input terminal of the instance X202. At this step, the line delay time of the line X203 is a delay X210; the line delay time of the line X204 is a delay X212; and the delay time of the instance X201 is a delay X211.

At the instance input signal waveform calculation step SX101, the signal waveforms input to the instances, which vary due to the Miller effect, are recalculated using a variable capacitance value X100 that describes the variation of the terminal capacitance which varies due to the Miller effect in each cell and the input/output signal waveforms X101. At step SX101, the recalculation is carried out with the coupling capacitance X205 added between the input and output terminals of the instance X201 of FIG. 12A for representation of the input signal waveform with consideration for the Miller effect.

Furthermore, at step SX101, the influence of a signal variation at the output terminal of the instance X201 on the line X204 is calculated. In the meantime, a crosstalk calculation of the output-side line X204 of the instance X201 with respect to the input-side line X203 of the instance X201 is carried out with the line X204 as an aggressor and the line X203 as a victim. As a result, an input signal waveform X213 of the instance X201 shown in FIG. 12B is obtained.

At the instance output signal waveform transfer step SX102, an output signal waveform X214 to be transferred of the instance X201 is calculated from the signal waveform X213 input to the instance X201 and RC information of the line X204 with consideration for the Miller effect as shown in FIG. 12B. The data of the output signal waveform X214 is stored in a Miller effect-considered output signal waveform X103 of FIG. 11.

At the second delay time calculation step SX103, the output signal waveform X103 obtained at the instance output signal waveform transfer step SX102, in which the Miller effect is considered, is used to perform the delay time calculation again on all of the instances and lines. Specifically, the Miller effect-considered input signal waveform X102 obtained at step SX101 and the Miller effect-considered output signal waveform X103 obtained at step SX102 are used. The time interval between the threshold voltages of the waveforms X102 and X103 is assumed as a delay time. As shown in FIG. 12B, a line delay time X216 of the line X203 is calculated from the output signal waveform X206 and the input signal waveform X213; a delay time X217 of the instance X201 is calculated from the input signal waveform X213 and the output signal waveform X214; and a line delay time X218 of the line X204 is calculated from the output signal waveform X214 and the input signal waveform X215.

As described above, a bump is generated by expressing the variation of the input terminal capacitance of an instance as a coupling capacitance, whereby a variation of a signal waveform which is caused due to the Miller effect is expressed.

According to the method described in embodiment 5, delay time calculation and timing analysis can be carried out with consideration for the signal waveform and delay time which vary due to the Miller effect. Thus, a timing error caused by the Miller effect can be avoided.

Especially in a gate which has a structure where a signal passes through only one transistor gate between the inlet and outlet of the gate (e.g., an inverter, NAND, NOR, or the like), a waveform blunted at the input terminal of the gate is likely to influence the output of the gate. Thus, the delay time calculation can be carried out with high accuracy by using the method of embodiment 5 of the present invention.

### Embodiment 6

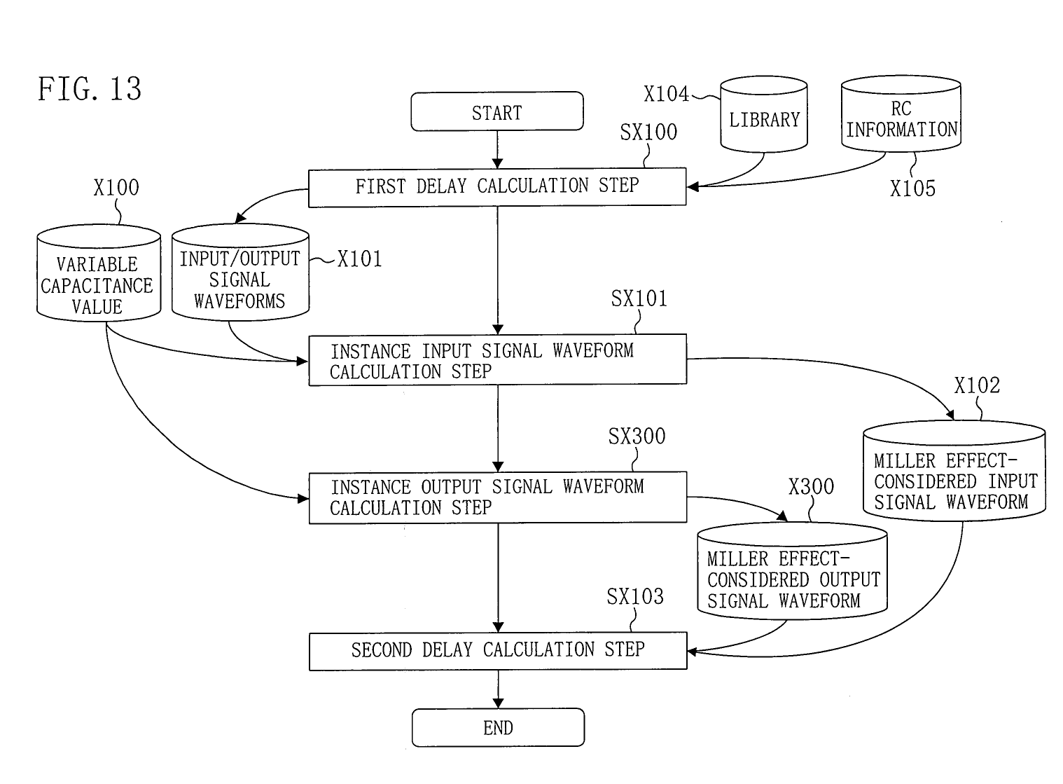

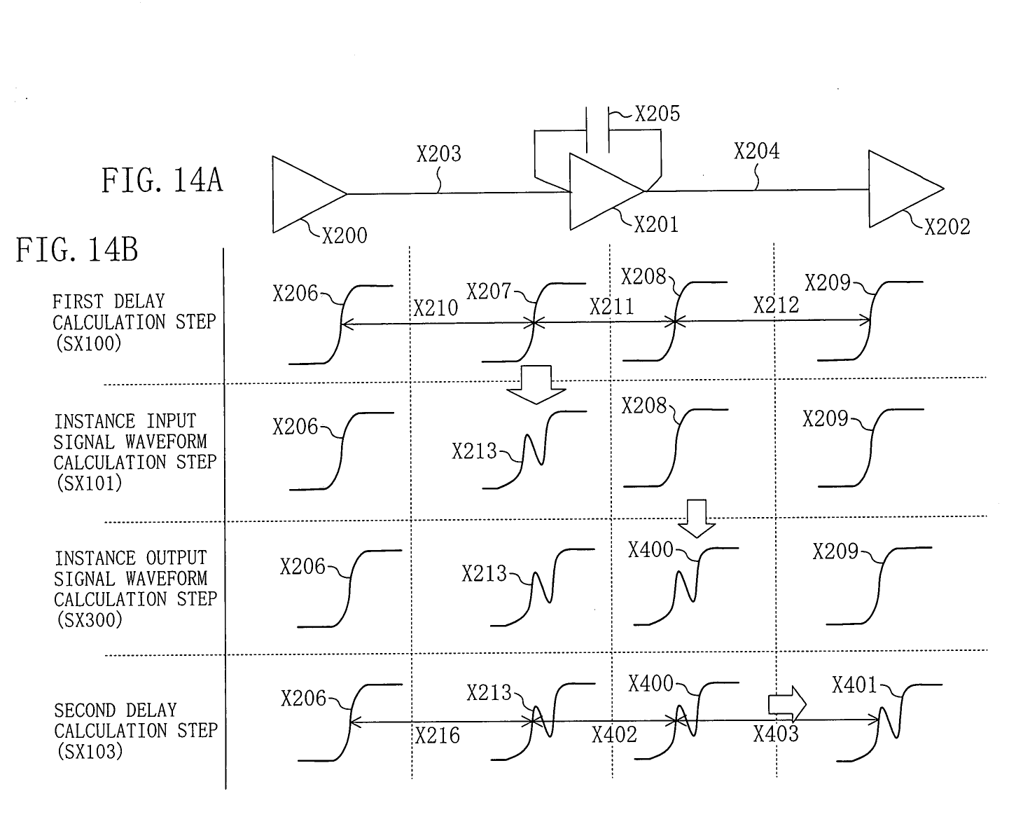

Embodiment 6 of the present invention is described with reference to FIGS. 13 and 14.

FIG. 13 is a flowchart of a delay time calculation process in which a delay variation caused due to the Miller effect is considered.

The instance output signal waveform calculation step SX300 of embodiment 6 is different from the instance output signal waveform transfer step SX102 of embodiment 5 in that the variable capacitance value X100 is used as an input value.

FIG. 14A shows a specific example of a circuit subjected to the delay time calculation process. The circuit of FIG. 14A is the same as that of FIG. 12A of embodiment 5, and therefore, the descriptions thereof are herein omitted. The chart of FIG. 14B is substantially the same as that of FIG. 12B of embodiment 5 except that the instance output signal waveform calculation step SX300 replaces the instance output signal waveform transfer step SX102 of embodiment 5, wherein the waveform at the output terminal of the instance X201 is a waveform X400 as shown in FIG. 14B. At the second delay time calculation step SX103, the voltage at the output terminal of the instance X201 has a waveform X400, and the voltage at the input terminal of the instance X202, which is derived from the waveform X400, has a waveform X401. The delay time of the instance X201, i.e., the delay between the waveforms X213 and X400 at the input and output terminals of the instance X201, is a delay time X402. The line delay of the line X204 is a line delay time X403.

The flowchart of FIG. 13 is now described with reference to FIGS. 14A and 14B.

In FIG. 13, the first delay time calculation step SX100 and the instance input signal waveform calculation step SX101 are the same as those of the flowchart shown in FIG. 11 of embodiment 5. It should be noted that, in embodiment 6, a netlist of a design, setting of a boundary and/or timing restrictions may also be read in for delay time calculation, in addition to the delay library X104 and RC information X105 which are read in at the first delay time calculation step SX100, as in embodiment 5.

In this calculation with the circuit structure shown in FIG. 14A, the Miller effect is not considered at step SX100, which is the same in embodiment 5. Therefore, the coupling capacitance X205 is omitted from the calculation of waveforms and the calculation of delay times based on the calculated waveforms.

At the instance input signal waveform calculation step SX101, the signal waveforms input to the instances, which vary due to the Miller effect, are recalculated using a variable capacitance value X100 that describes the variation of the terminal capacitance which varies due to the Miller effect in each cell and the input/output signal waveforms X101. At step SX101, the recalculation is carried out with the coupling capacitance X205 added between the input and output terminals of the instance X201 of FIG. 14A for representation of the input signal waveform with consideration for the Miller effect.

Furthermore, at step SX101, the influence of a signal variation at the output terminal of the instance X201 on the line X204 is calculated. In the meantime, a crosstalk calculation is carried out with the line X204 as an aggressor and the line X203 as a victim. As a result, an input signal waveform X213 of the instance X201 shown in FIG. 14B is obtained.

At the instance output signal waveform calculation step SX300, an output signal waveform X400 of the instance X201 is calculated from the variable capacitance value X100 that describes the variation of the terminal capacitance which varies due to the Miller effect in each cell and the input/output signal waveforms X101 of the instance X201 (the input signal waveform X207 and the output signal waveform X208 of FIG. 14B). The details of this calculation are the same as those of the calculation of the input signal waveform X213 which varies due to the Miller effect at step SX101.

In the recalculation of the output signal waveform of the instance X201 at step SX300, for representation of the output signal waveform with consideration for the Miller effect, the influence of a signal variation at the input terminal of the instance X201 of FIG. 14A on the line X203 is calculated using the circuit of FIG. 14A which includes the coupling capacitance X205 added between the input and output terminals of the instance X201. Furthermore, a crosstalk calculation is carried out with the line X203 as an aggressor and the line X204 as a victim. As a result, the output signal waveform X400 shown in FIG. 14B, in which the Miller effect is considered, is output from the instance X201. The data of the output signal waveform X400 is stored in a Miller effect-considered output signal waveform X300 of FIG. 13.

At the second delay time calculation step SX103, the output signal waveform data X103 obtained at the instance output signal waveform calculation step SX300, in which the Miller effect is considered, is used to perform the delay time calculation again on all of the instances and lines. According to this delay recalculation method, a calculation is carried out while the signal waveform calculated in the above process is assumed as the time interval between their threshold voltages. As shown in FIG. 14B, a line delay time X216 of the line X203 is calculated from the output signal waveform X206 and the input signal waveform X213; a delay time X402 of the instance X201 is calculated from the input signal waveform X213 and the output signal waveform X400; and a line delay time X403 of the line X204 is calculated from the output signal waveform X400 and the input signal waveform X401.

As described above, a bump is generated by expressing the variation of the input terminal capacitance of an instance as a coupling capacitance, whereby a variation of a signal waveform which is caused due to the Miller effect is expressed.

According to the method described in embodiment 6, delay time calculation and timing analysis can be carried out with consideration for the signal waveform and delay time which vary due to the Miller effect. Thus, a timing error caused by the Miller effect can be avoided.

Especially in a gate which has a structure where a signal passes through a plurality of transistor gates (e.g., a buffer, AND, OR, or the like), a waveform blunted at the input terminal of the gate is unlikely to influence the output of the gate. Thus, in such a case, even when the method described in embodiment 6 (i.e., a method which uses the capacitance value variable due to the Miller effect even in the process of obtaining an instance output signal waveform as in the process of obtaining an instance input signal waveform) is used in place of the method described in embodiment 5, the delay time calculation can be carried out with high accuracy.

### Embodiment 7

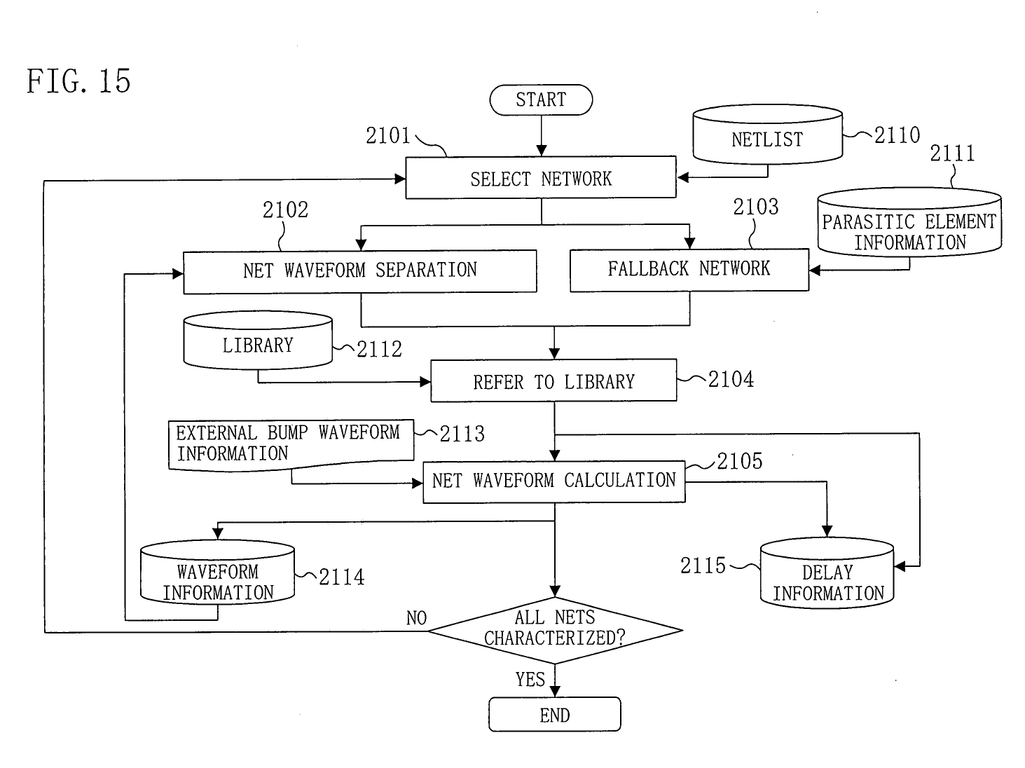

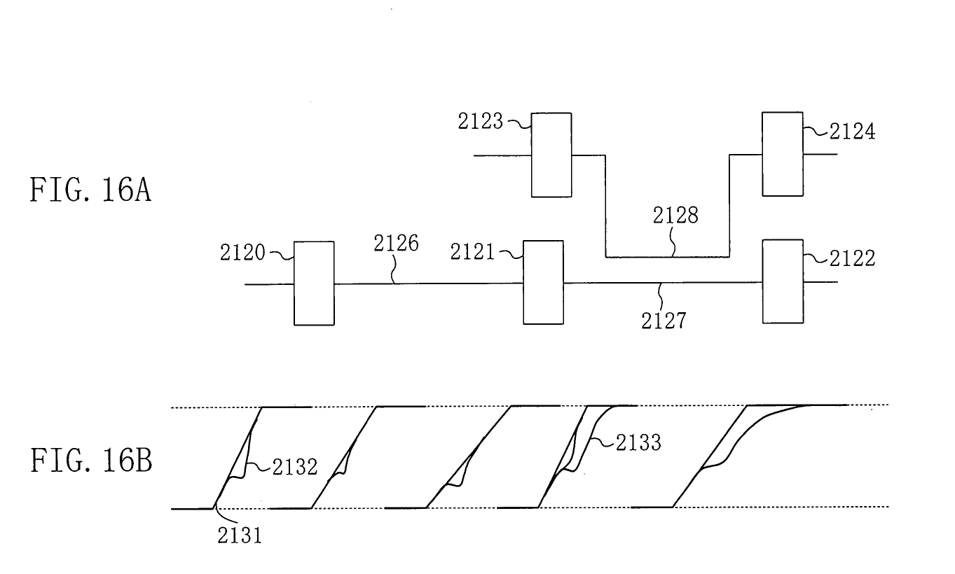

Embodiment 7 of the present invention is described with reference to FIGS. 15 and 16.

FIG. 15 is a flowchart of a delay time calculation process in which a bump-superimposed waveform is considered. FIG. 16A shows a specific example of networks which are subjects of the delay time calculation process in which a bump-superimposed waveform is considered. FIG. 16A shows the first and second networks. The first network (lower) includes Instance_1 2120, Instance_2 2121 and Instance_3 2122. Instance_1 2120 and Instance_2 2121 are connected through Net_1 2126. Instance_2 2121 and Instance_3 2122 are connected through Net_2 2127. The second network (upper) includes Instance_A1 2123 and Instance_A2 2124 which are connected through Net_A1 2128. The first and second networks are placed closer to each other at Net_2 2127 and Net_A1 2128. FIG. 16B shows the waveforms at respective points on the first network. The waveform at each point includes an input slope waveform 2131. Reference numeral 2132 denotes a bump waveform. Reference numeral 2133 denotes an external bump (crosstalk) waveform.

The flowchart of FIG. 15 is now described with reference to FIGS. 16A and 16B.

Referring to FIG. 15, at the network selection step 2101, a net which is to be subjected to a delay time calculation is selected from a netlist 2110 that describes connection information of a design. It is assumed herein that, in the first place, Net_1 2126 on the first network is selected.

At the net waveform separation step (input slope waveform/bump waveform separation step) 2102, a waveform input to Instance_1 2120 described in waveform information 2114, which includes a superimposed bump, is divided into an input slope waveform 2131 and a bump waveform 2132 shown in FIG. 16B. In this step, the slew rate value of the input slope waveform, the bump height and bump width of the bump waveform, the timing at which the bump is superimposed on the waveform, the time that elapses till the bump reaches the peak, and the bump area are obtained.

At the network fallback step 2103, a circuit which is formed by Net_1 2126 and the input terminal capacitance of Instance_2 2121 at the next stage falls back based on parasitic element information 2111. In this step, the drive load of Instance_1 2120 is obtained.

At the library reference step 2104, a library 2112 which is prepared based on the cell characteristic characterization method described in embodiment 2 when a bump waveform is superimposed on a waveform (corresponding to the table data 1315 of FIG. 4) is used to obtain a cell delay and an output waveform which is represented by a waveform including a superimposed bump waveform. The cell delay is recorded in delay information 2115.

At the net waveform calculation step 2105, waveform analysis is carried out based on the output waveform of Instance_1 2120 which is obtained at the library reference step 2104. In this analysis, the line delay value of Net_1 2126 and the input waveform of Instance_2 2121 are calculated. The line delay value of Net_1 2126 is recorded in the delay information 2115, and the input waveform of Instance_2 2121 is recorded in waveform information 2114.

Next, it is assumed that, at the network selection step 2101, the second network of FIG. 16A is selected.

At the net waveform separation step 2102, the waveform input to Instance_2 2121 described in the waveform information 2114, which includes a superimposed bump, is separated into an input slope waveform and a bump waveform.

At the network fallback step 2103, a circuit which is formed by Net_2 2127 and the input terminal capacitance of Instance_3 2122 at the next stage falls back based on the parasitic element information 2111. In this step, the drive load of Instance_2 2121 is obtained.

At the library reference step 2104, the library 2112 is used to obtain a cell delay and an output waveform which is represented by a waveform including a superimposed bump waveform. The cell delay is recorded in delay information 2115.

As for Net_2 2127, Net_A1 2128 which has a coupling capacitance exists in the vicinity of Net_2 2127, and accordingly, interline crosstalk occurs therebetween. The interline crosstalk causes an external bump waveform 2133. The external bump waveform 2133 is calculated through another process and described in external bump waveform information 2113. Thus, at the net waveform calculation step 2105, waveform analysis is carried out using a waveform which is formed by the output waveform of Instance_2 2121 obtained at the library reference step 2104 and the external bump waveform 2133 superimposed thereon, whereby the line delay value of Net_2 2127 and the input waveform of Instance_3 2122 are calculated. The line delay value of Net_2 2127 is recorded in the delay information 2115, and the input waveform of Instance_3 2122 is recorded in the waveform information 2114.

It should be noted that superimposition of the external bump waveform may be determined in consideration of the transition timing of Net_A1 2128 and the transition timing of Net_2 2127. For example, when Net_A1 2128 and Net_2 2127 do not transition at the same time, the external bump waveform may not be superimposed.

In the example of embodiment 7, the cause of the external bump waveform is crosstalk. However, the cause may be simultaneous switching noise, overshoot or undershoot due to inductance, or the like.

This series of steps for delay time calculation is repeated till the delay time calculation is performed on all of the nets described in the netlist 2110.

As described above, according to embodiment 7, even when waveform distortion is caused by crosstalk, simultaneous switching (simultaneous transition) noise, overshoot or undershoot due to inductance, or the like, delay time calculation can be performed with high accuracy with consideration for the influence of the waveform distortion.

### Embodiment 8

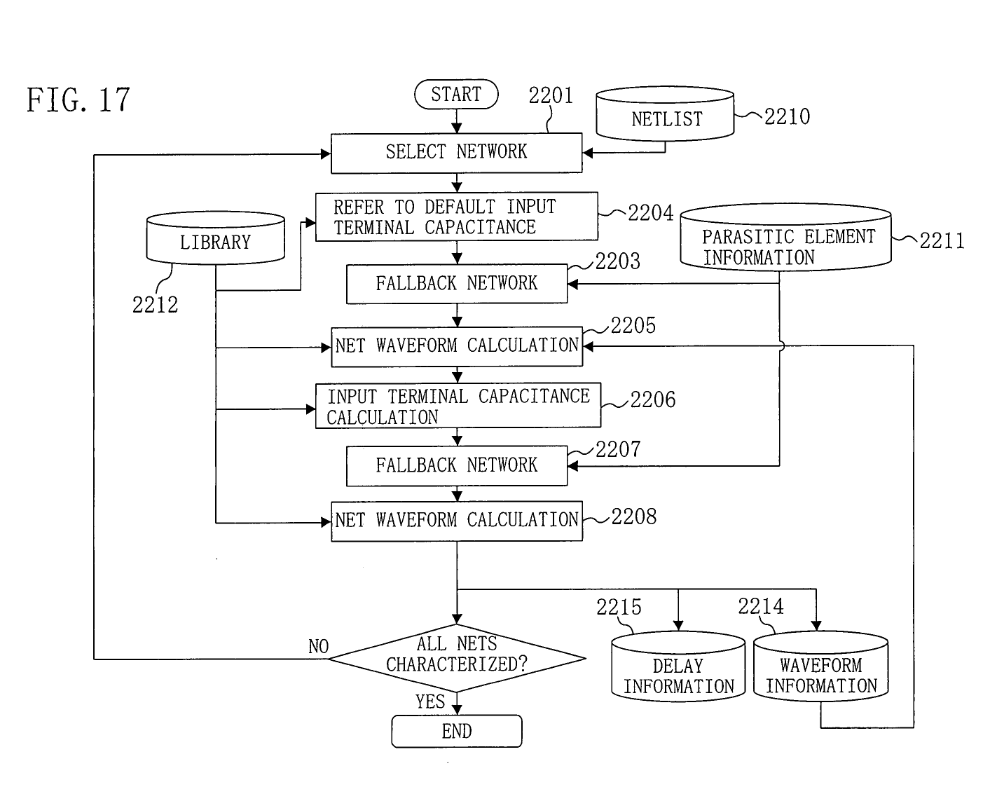

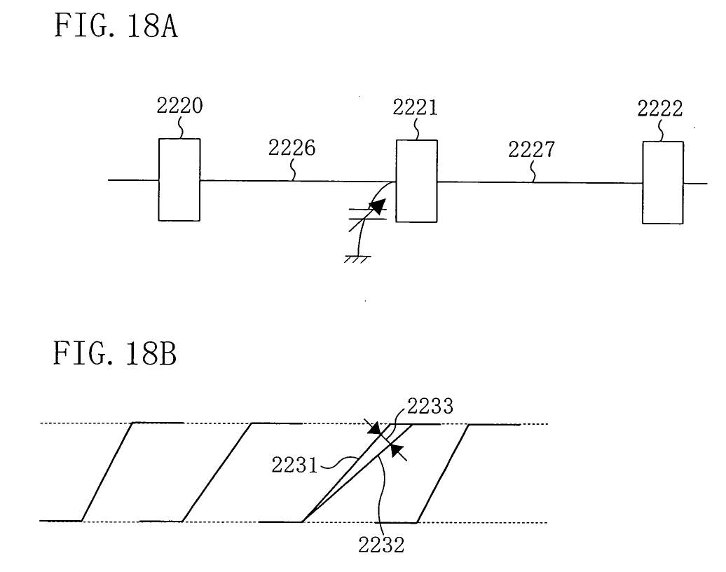

Embodiment 8 of the present invention is described with reference to FIGS. 17 and 18.

FIG. 17 is a flowchart of a delay time calculation method of embodiment 8 in which a variable input terminal capacitance is considered. FIG. 18A shows a specific example of a network which is a subject of a delay time calculation process in which a variable input terminal capacitance is considered. In the network of FIG. 18A, Instance_1 2220 and Instance_2 2221 are connected through Net_1 2226, and Instance_2 2221 and Instance_3 2222 are connected through Net_2 2227. At the input terminal of Instance_2 2221, an equivalent input terminal capacitance 2230 is added for consideration of the variable input terminal capacitance. FIG. 18B shows the signal waveforms at respective points in the network of FIG. 18A. At the input terminal of Instance_2 2221, the waveform which is input to Instance_2 2221 before a variation of the equivalent input terminal capacitance is a waveform 2231, and the waveform which is input to Instance_2 2221 after a variation of the equivalent input terminal capacitance is a waveform 2232.

The flowchart of FIG. 17 is now described with reference to FIGS. 18A and 18B.

Referring to FIG. 17, at the network selection step 2201, a net which is to be subjected to a delay time calculation and a net subsequent thereto are selected from a netlist 2210 which describes connection information of a design. In the example of FIG. 18A, it is assumed that Net_1 2226 and Net_2 2227 are selected.

At the default input terminal capacitance reference step 2204, as for an instance connected between the net which is a subject of delay time calculation and the subsequent net, a library 2212 in which the input terminal capacitance is characterized as the function of the input slew rate and the drive load according to the characterization method described in embodiment 1 is referred to, and the input terminal capacitance which is obtained when the Miller effect is not caused is extracted. In the example of FIG. 18A, the library 2212 is referred to as to Instance_2 2221 and Instance_3 2222. At the network fallback step (first network fallback step) 2203, as for the net which is a subject of delay time calculation and the subsequent net, a network circuit which includes a parasitic element of parasitic element information 2211 and a circuit which includes the input terminal capacitance of an instance of the subsequent stage fall back to effective input terminal capacitances whose loads are effectively the same. In the example of FIG. 18A, a network circuit formed by the Net_1 2226 and Instance_2 2221 falls back, and a circuit formed by the Net_2 2227 and Instance_3 2222 falls back.

At the net waveform calculation step (first net waveform calculation step) 2205, the library 2212 is referred to using the output slew rate of a net previous to Net_1 2226, i.e., the input slew rate of Instance_1 2220, which is obtained from waveform information 2214, and the pre-variation input terminal capacitance (load section) of the network circuit which has fallen back at step 2203 (i.e., a circuit formed by Net_1 2226 and Instance_2 2221) as indices to calculate the cell output slew rate of Instance_1 2220. Furthermore, the waveform 2231 obtained before a variation of the effective input terminal capacitance, which is the output slew rate of Net_1 2226, is calculated by waveform analysis.

At the input terminal capacitance calculation step 2206, the library 2212 is referred to using the slew rate of the waveform 2231 which is obtained before a variation of the effective input terminal capacitance of Instance_2 2221 (i.e., obtained when the input waveform includes no distortion) and the load capacitance of Net_2 2227 which has fallen back at step 2203 as indices to calculate the post-variation effective input terminal capacitance of Instance_2 2221.

At the network fallback step (second network fallback step) 2207, a circuit formed by a net which is a subject of delay time calculation and the post-variation effective input terminal capacitance of an instance at the next stage which is connected to the net falls back. In the example described herein, a circuit formed by Net_1 2226 and the post-variation effective input terminal capacitance of Instance_2 2221, which has been calculated previously, falls back.

At the net waveform calculation step (second net waveform calculation step) 2208, the library 2212 is referred to using the output slew rate of a net previous to Net_1 2226 (i.e., the input slew rate of Instance_1 2220), which is obtained from waveform information 2214, and the load section which has fallen back (i.e., a circuit obtained as a result of the fallback of the circuit formed by Net_1 2226 and the post-variation effective input terminal capacitance of Instance_2 2221) as indices to calculate the cell delay value and cell output slew rate of Instance_1 2220. The cell delay value and the cell output slew rate of Instance_1 2220 are recorded in the waveform information 2214 and the delay information 2215, respectively. Furthermore, a waveform 2232 obtained after a variation of the effective input terminal capacitance, which is the output slew rate of Net_1 2226, and the line delay time of Net_1 2226 are calculated by waveform analysis and recorded in the waveform information 2214 and the delay information 2215, respectively.

A series of steps for the above-described delay time calculation is repeated till the delay time calculation is performed on all of the nets described in the netlist 2210.

As described above, according to embodiment 8, even when waveform distortion is caused due to the Miller effect, the delay time calculation can be performed with high accuracy in consideration of the influence of the waveform distortion in consideration of the influence of the waveform distortion by using a model of the variation of the effective input terminal capacitance.

### Embodiment 9

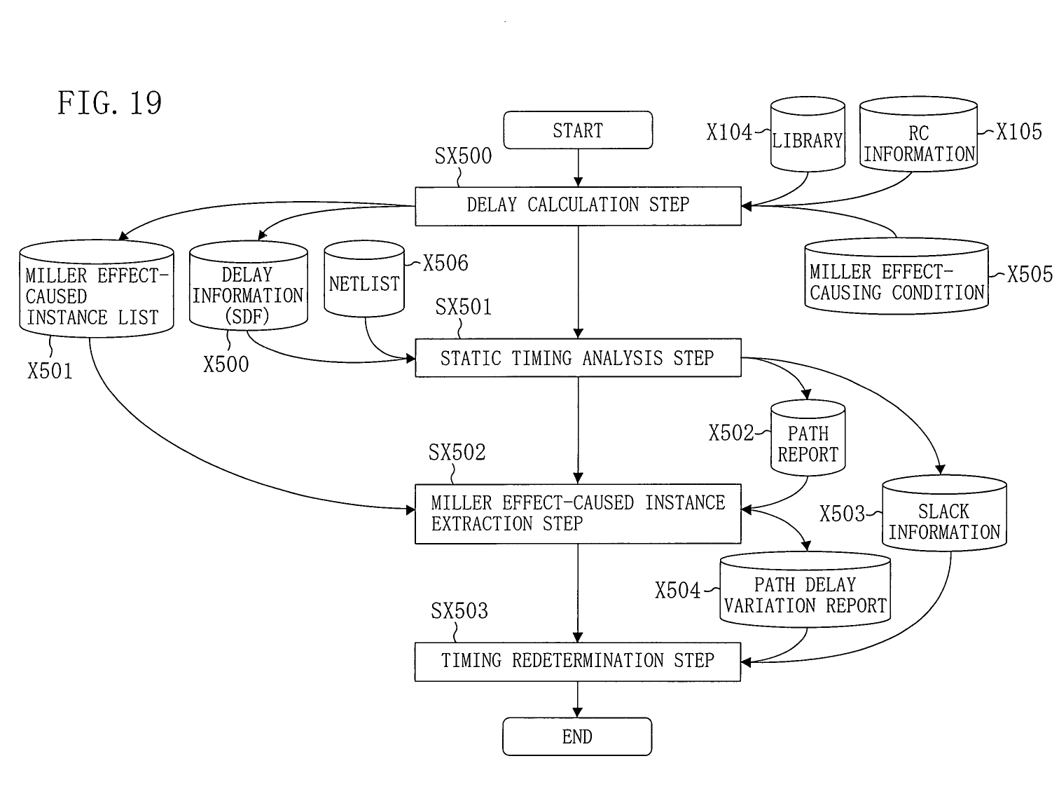

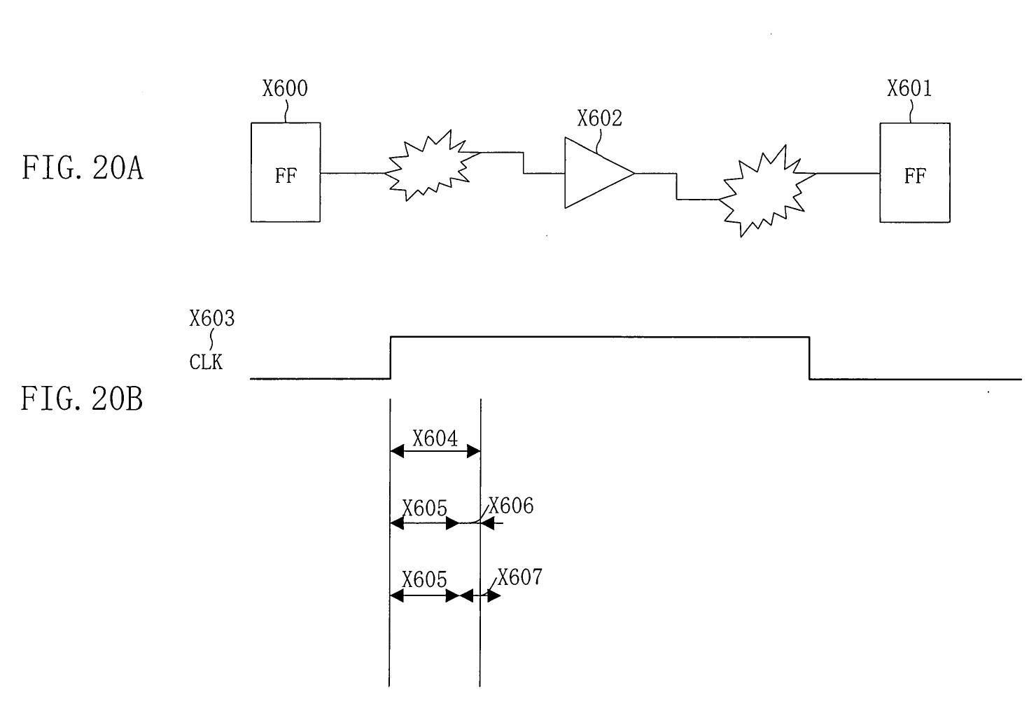

Embodiment 9 of the present invention is described with reference to FIGS. 19 and 20.

FIG. 19 illustrates a timing redetermination method for a case where, in a timing analysis, a path that fails to satisfy the timing includes an instance in which the Miller effect occurs.

The method of FIG. 19 includes: a delay time calculation step (SX500) for calculating the delay time of all the instances and lines in a design and extracting an instance in which the Miller effect occurs; a static timing analysis step (SX501) for performing timing analysis based on the delay information calculated at the delay time calculation step SX500; a Miller effect-caused instance extraction step (SX502) for determining whether or not the Miller effect is caused in an instance included in a path which fails to satisfy the timing and, if so, calculating the delay variation caused by the Miller effect; and a timing redetermination step (SX503) for performing the timing analysis again based on the delay variation caused by the Miller effect and the timing report of the path. Reference numeral X500 denotes delay information which describes the delay time of all the instances and lines in a design. Reference numeral X501 denotes a Miller effect-caused instance list which lists the instances in which the Miller effect is caused. Reference numeral X502 denotes a path report which describes the timing information of a path which fails to satisfy the timing as a result of the timing analysis and the instances which constitute the path. Reference numeral X503 denotes slack information which describes a slack value of the path which fails to satisfy the timing as a result of the timing analysis. Reference numeral X504 denotes a path delay variation report which describes the delay variation of an instance in which the Miller effect is caused. Reference numeral X505 denotes a Miller effect-causing condition which describes for each cell the condition(s) that causes the Miller effect. Reference numeral X506 denotes a netlist.

FIGS. 20A and 20B show a specific example of the process flow of FIG. 19. In the example of FIG. 20A, an instance X602 is inserted in a path extending from a flip flop X600 to a flip flop X601. FIG. 20B is a timing chart of clock signal X603 which is input to the flip flops X600 and X601 of FIG. 20A. FIG. 20B illustrates the time relationship of clock signal X603, which is input to the flip flops X600 and X601 of FIG. 20A, with a hold time X604 for a rising of clock CLK (X603) of FIG. 20B, an inter-flip flop (FF) path delay X605 which is compared with the hold time X604, a difference X606 obtained by subtracting the inter-FF path delay X605 from the hold time X604, and a delay variation X607 caused by the Miller effect with respect to the inter-FF path delay X605.

The flowchart of FIG. 19 is now described with reference to FIGS. 20A and 20B.

In the delay time calculation step SX500, the delay time and line delay time of all the instances in a design are calculated based on the delay library X104 and RC information X105. In the meantime, it is determined, for each instance, from the input signal waveform slope of the instance and a load capacitance to be driven according to the Miller effect-causing condition X505 whether or not the Miller effect is caused. Then, the instance(s) in which the Miller effect is caused is output as the Miller effect-caused instance list X501. The Miller effect-causing condition X505, which is used at the delay time calculation step SX500, describes the input signal waveform slope and the capacitance value for each cell type. As for each cell, if an input signal waveform has a slope larger than the input signal waveform slope and there is an instance which drives a capacitance smaller than the capacitance value, it is determined that the Miller effect is caused in the cell.

It should be noted that, in the example of embodiment 9, the delay library X104 and the RC information X105 are read in at the delay time calculation step SX500. However, a netlist of a design, setting of a boundary and/or timing restrictions may be additionally read in for delay time calculation. In this specification, the “cell” means a logic-level element, such as a buffer, an inverter, or the like, and the “instance” is only a name for distinguishing a plurality of cells of the same type.

Then, at the static timing analysis step SX501, the delay value of the delay information X500 is assigned to the netlist X506 to carry out a timing analysis.

If in the timing analysis there is a path which fails to satisfy the timing, the path report X502 which describes a list of instances that constitute the path and the slack information X503 which describes the unsatisfied time for the timing the path has to keep are output.

For example, assuming that the path found at step SX501 is a path which extends from the flip flop X600 to the flip flop X601 through the instance X602 as described in FIG. 20A, the path report X502 lists the flip flop X600, the flip flop X601, the instance X602, and other constituent instances.

Further, assuming that the specification the delay of the path has to satisfy is, for example, the hold time X604 as shown in FIG. 20B, the delay of the path is compared with the inter-FF path delay X605 of the path to determine which is longer than the other. If the delay of the path fails to satisfy the specification, the difference X607 (=“inter-FF path delay X605”-“hold time X604”) is output to the slack information X503.

Then, at the Miller effect-caused instance extraction step SX502, it is determined whether or not an instance described in the Miller effect-caused instance list X501 is included in the path report X502. If included, the delay variation caused by the Miller effect in the instance is output as the path delay variation report X504.

For example, assuming that the instance X602 is included in the Miller effect-caused instance list X501, it is determined that the Miller effect is caused in the path between the flip flops X600 and X601, and the delay variation X606 caused by the Miller effect in the instance X602 is calculated.

The method used herein for calculating the delay variation caused by the Miller effect may be the method described in embodiment 3 or 4. Alternatively, the delay variation may be calculated using a circuit simulator.

Lastly, at the timing redetermination step SX503, the slack information X503 and the path delay variation report X504 are compared. A path for which the value described in the slack information X503 is larger than the value described in the path delay variation report X504 is determined to satisfy the timing.

Further, the difference X607 and the delay variation X606 are compared. If the delay variation X606 is larger than the difference X607, the path fails to satisfy the timing. However, when an increase in the delay due to the Miller effect is considered, the path satisfies the timing. Thus, in such a case, it is determined that the path satisfies the timing.

As described above, according to embodiment 9, a path which fails to satisfy the timing as it is but satisfies the timing when an in crease in the delay occurs due to the Miller effect is determined not to have to be subjected to circuit modification. Thus, it is not necessary to make an additional circuit modification. Accordingly, the number of steps can be reduced, and an increase in area can be suppressed.

### Embodiment 10

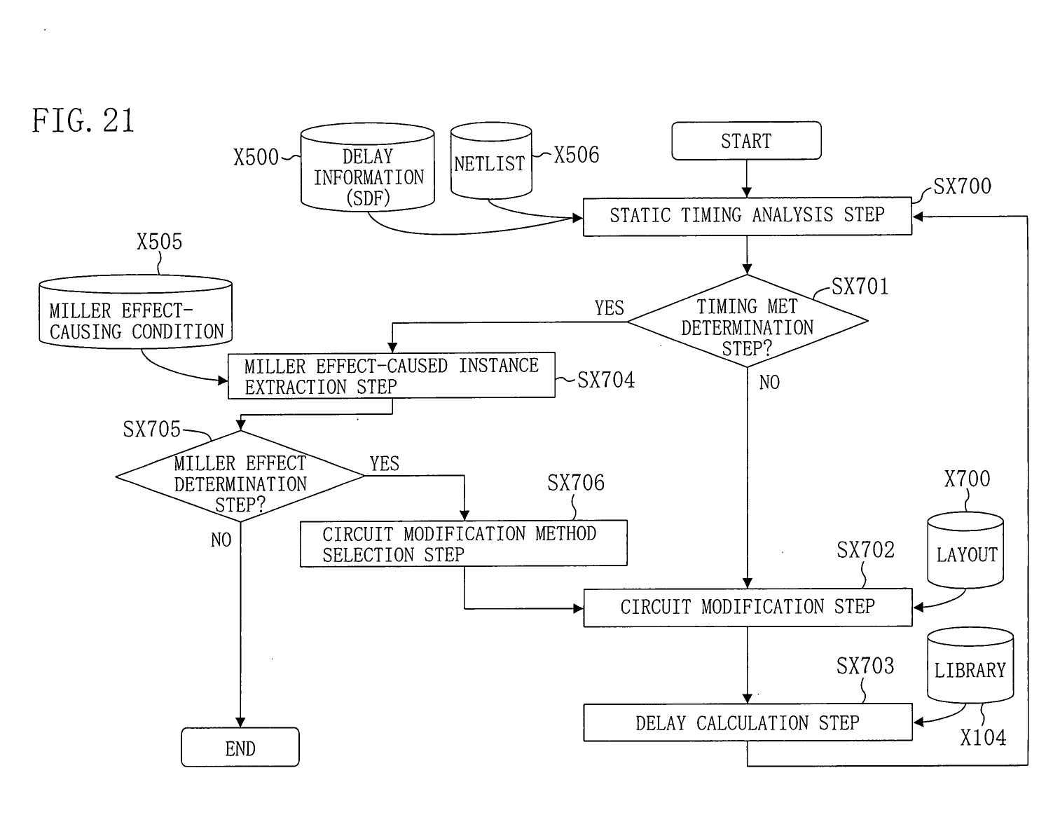

Embodiment 10 of the present invention is described with reference to FIGS. 21, 22 and 23.

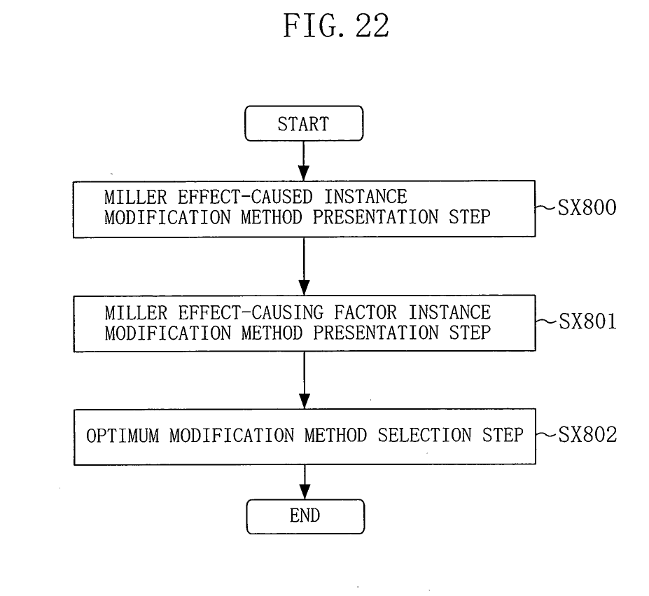

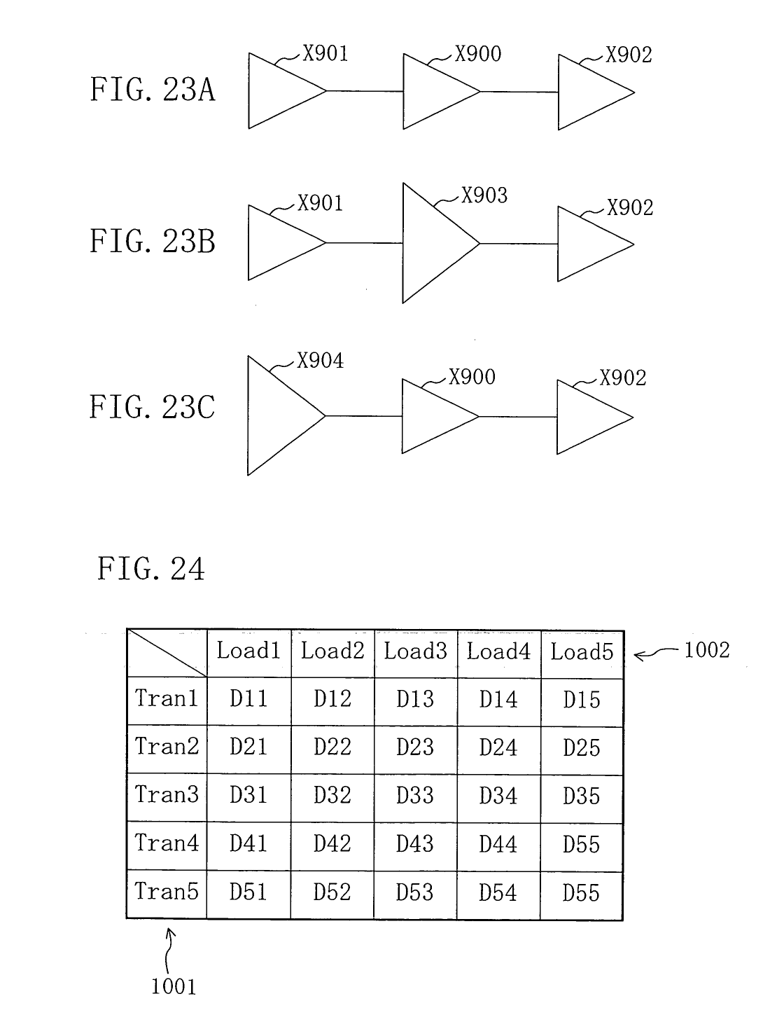

FIG. 21 is a flowchart of a timing correction process in which the Miller effect is considered. FIG. 22 illustrates the process of selecting an optimum circuit modification method. FIG. 23 illustrates examples of the optimum circuit modification method.

The method of FIG. 21 includes: a static timing analysis step (SX700) for performing a static timing analysis; a timing MET determination step (SX701) for determining whether or not the timing satisfies a timing design specification as a result of the timing analysis; a circuit modification step (SX702) for modifying a circuit such that the timing satisfies the timing design specification; a delay time calculation step (SX703) for calculating the delay time of all the instances and lines in a design; a Miller effect-caused instance extraction step (SX704) for extracting an instance in which the Miller effect is caused; a Miller effect determination step (SX705) for determining whether or not the Miller effect is caused; and a circuit modification method selection step (SX706) for selecting a circuit modification method which causes the minimum area damage in a circuit modification process. Reference numeral X700 denotes a layout.

The process of FIG. 22 includes: a Miller effect-caused instance modification method presentation step (SX800), a Miller effect-causing factor instance modification method presentation step (SX801), and an optimum modification method selection step (SX802). At the Miller effect-caused instance modification method presentation step SX800, a circuit modification method is presented with which, based on the input signal waveform and load capacitance of an instance in which the Miller effect is caused, the cell size of the instance in which the Miller effect is caused is changed such that the Miller effect is removed. In the Miller effect-causing factor instance modification method presentation step SX801, a circuit modification method is presented with which the cell size of an instance connected to an input or output terminal of an instance in which the Miller effect is caused (i.e., an instance which is a factor of the Miller effect) is changed to change the input signal waveform or load capacitance of the instance in which the Miller effect is caused such that the Miller effect is removed. In the optimum modification method selection step SX802, the method presented at the Miller effect-caused instance modification method presentation step SX800 and the method presented at the Miller effect-causing factor instance modification method presentation step SX801 are compared as to which method causes the minimum area damage to select the optimum circuit modification method.

FIG. 23A shows an instance X900 in which the Miller effect is caused, an instance X901 which is connected to the input terminal of the instance X900, and an instance X902 which is connected to the output terminal of the instance X900. In FIG. 23B, reference numeral X903 denotes an instance obtained by changing the cell size of the instance X900 such that the Miller effect is removed. In FIG. 23C, reference numeral X904 is an instance obtained by changing the cell size of the instance X901 such that the Miller effect is removed from the instance X900.

The flowchart of FIG. 21 is now described with reference to FIGS. 22 and 23.

Firstly, at the static timing analysis step SX700, the delay information X500 is assigned to the netlist X506, and a static timing analysis is carried out.

Then, at the timing MET determination step SX701, it is determined whether or not the timing satisfies the specification as a result of the static timing analysis. If the timing is not satisfied (“NO” at step SX701), the process proceeds to the circuit modification step SX702.

At the circuit modification step SX702, the layout X700 is read in, and change of the cell size, rearrangement of lines, or the like, is carried out, whereby the timing is corrected.

Then, at the delay time calculation step SX703, the delay time of all the instances and lines in the timing-corrected design is calculated, and the process returns to the static timing analysis step SX700. The above steps are repeated till the timing satisfies the specification.

If the timing satisfies the specification at the timing MET determination step SX701, the process proceeds to the Miller effect-caused instance extraction step SX704.

At the Miller effect-caused instance extraction step SX704, when instances which constitute a path having a timing error meet the Miller effect-causing condition X505, the instances are extracted.

Then, at the Miller effect determination step SX705, it is determined whether or not the instances extracted at the Miller effect-caused instance extraction step SX704 include an instance in which the Miller effect is caused. If there is such an instance (“YES” at step SX705), it is determined that a circuit modification is necessary. Then, at the circuit modification method selection step SX706, a circuit modification method is selected, and the process proceeds to the circuit modification step SX702. If there is not an instance in which the Miller effect is caused (“NO” at step SX705), it is determined that the timing correction has been completed, and the process is terminated.

The circuit modification method selection step SX706 of the above process is now described in detail using the flowchart of FIG. 22 and the circuit diagrams of FIGS. 23A to 23C.

The circuit modification method selection step SX706 includes the Miller effect-caused instance modification method presentation step SX800, the Miller effect-causing factor instance modification method presentation step SX801, and the optimum modification method selection step SX802 as shown in FIG. 22.

In the circuit of FIG. 23A, if the Miller effect is caused in the instance X900, a method for changing the driving capacity (cell size) of the instance X900 such that the Miller effect is removed is presented at step SX800. It is assumed herein that, as a result of the change by the presented method, the instance X900 is changed into the instance X903 of FIG. 23B.

Since the Miller effect is caused by a signal waveform input to the instance and the load capacitance, it is then determined whether or not the modification can be realized by changing the signal waveform input to the instance X900 or the load capacitance.

At the Miller effect-causing factor instance modification method presentation step SX801, a method for changing the cell size of the instance X901 to change the signal waveform input to the instance X900 in which the Miller effect is caused is presented. In the change of cell size by the presented method, in general, the cell size of the instance X901 is increased (i.e., the driving capacity is improved) to the size of the instance X904 as shown in FIG. 23C such that the signal waveform has a sharp slope. Alternatively, when the load capacitance is considered, the size of the instance X902 may be changed.

At the optimum modification method selection step SX802, the increase in area due to the change of cell size is compared between the instance X903 and the instance X904, and one of the methods presented at step SX800 and step SX801 which causes the smaller area damage is selected.

At the circuit modification step SX702, the circuit layout is modified using the method selected at step SX802.

As described above, at the occasion of timing correction, it is determined whether or not there is an instance in which a delay variation occurs due to the Miller effect, and the circuit modification method which causes the minimum area damage is presented. Thus, the Miller effect is avoided with the minimum damage, and teething troubles at the market can be prevented before they happen.

1. A cell characteristic characterization method for characterizing the characteristics of a cell to which a predetermined drive load is connected, where an input waveform to the cell has a distortion due to the Miller effect, the method comprising:
an effective input terminal capacitance calculation step of calculating an effective input terminal capacitance of the cell which corresponds to a case where the input waveform input to the characterization subject cell to which the drive load is connected results in a distorted waveform which is delayed from the input waveform by a predetermined delay time due to the Miller effect; and
a storage step of storing the effective input terminal capacitance calculated at the effective input terminal capacitance calculation step as a function of the input waveform and the value of the drive load.

2. A cell characteristic characterization method, comprising:
an input slope waveform generation step of generating an input slope waveform;
an input bump waveform generation step of generating an input bump waveform;
a circuit simulation step of inputting an input waveform which includes the input slope waveform and the input bump waveform superimposed thereon to the characterization subject cell and measuring an output waveform of the characterization subject cell which corresponds to the input waveform input to the characterization subject cell;
a slope waveform/bump waveform separation step of separating the measured output waveform of the characterization subject cell into an output slope waveform and an output bump waveform; and
a storage step of storing the output slope waveform and the output bump waveform as a function of the input slope waveform and the input bump waveform.

3. The method of claim 2, wherein each of the input bump waveform and the output bump waveform is defined by a waveform transition time of the slope waveform, a bump waveform height, a bump waveform width, a bump area, a time interval which elapses till the bump waveform reaches a peak, and a timing at which the bump waveform is superimposed on the slope waveform.

4. A cell characteristic characterization method for characterizing a characterization subject cell to which a predetermined drive load is connected, a cell which has a small driving capacity being connected to an input side of the characterization subject cell, the method comprising:
a waveform distortion detection step which includes
inputting an input waveform to the small driving capacity cell, and
detecting the presence/absence of a waveform distortion in an input waveform and an output waveform of the characterization subject cell as a result of the input waveform to the small driving capacity cell; and
a storage step of storing the presence/absence of the waveform distortion in the input waveform and the output waveform of the characterization subject cell as a function or table of the input waveform of the characterization subject cell and the value of the drive load.

5. A delay time calculation method for calculating a delay time of a semiconductor integrated circuit with consideration for a waveform distortion using the cell characteristic characterization method of claim 2, the semiconductor integrated circuit including a plurality of cells connected by a plurality of lines, the method comprising:
a drive load/input waveform extraction step of extracting an input waveform and a value of a drive load as to a delay time calculation subject cell selected from the plurality of cells;
a distortion-generating pattern determination step of referring to the function of the cell characteristic characterization method of claim 2 to determine whether or not a pattern of the delay time calculation subject cell which corresponds to the extracted input waveform and the extracted value of the drive load generates a distortion in the input waveform or the output waveform;
if the pattern is not determined to be a pattern which generates a distortion at the distortion-generating pattern determination step, a gate-level delay time calculation step of performing a gate-level delay time calculation process on the delay time calculation subject cell; and
if the pattern is determined to be a pattern which generates a distortion at the distortion-generating pattern determination step, a transistor-level delay time calculation step of performing a transistor-level delay time calculation process on the delay time calculation subject cell.

6. The delay time calculation method of claim 5, further comprising a waveform distortion detection step, which includes
detecting whether or not a waveform distortion occurs in an input waveform and an output waveform of the delay time calculation subject cell after the delay time calculation at the transistor-level delay time calculation step, and
if a waveform distortion occurs, repeating a transistor-level delay time calculation at the transistor-level delay time calculation step till the occurrence of the waveform distortion is stopped.

7. A delay time calculation method for calculating a delay time of a semiconductor integrated circuit with consideration for a waveform distortion, the semiconductor integrated circuit including a plurality of instances connected by a plurality of nets, the method comprising:
a first delay time calculation step of calculating a delay time of all the instances and a line delay time of all the nets and signal waveforms at input and output terminals of all the instances;
an instance input signal waveform calculation step of obtaining a distorted input signal waveform which is distorted due to the Miller effect of a delay time calculation subject instance selected from the plurality of instances, the instance input signal waveform calculation step including
inputting a variable input terminal capacitance value of the delay time calculation subject instance which is determined according to the presence/absence of a distortion caused by the Miller effect in an input waveform,
representing the variable input terminal capacitance value as a coupling capacitance between input and output terminals of the delay time calculation subject instance, and
calculating crosstalk using a net connected to the output terminal of the delay time calculation subject instance as an aggressor and a net connected to the input terminal of the delay time calculation subject instance as a victim;
an instance output signal waveform transfer step of obtaining a distorted output signal waveform of the delay time calculation subject instance, the instance output signal waveform transfer step including
inputting the distorted input signal waveform calculated at the instance input signal waveform calculation step, and
calculating a signal waveform transfer between the input and output terminals of the delay time calculation subject instance; and
a second delay time calculation step which includes
calculating a delay time of the delay time calculation subject instance based on the distorted input signal waveform and the distorted output signal waveform of the delay time calculation subject instance, and
allowing transfer of the distorted output signal waveform to calculate a delay time of a subsequent instance and a line delay time of a subsequent net.

8. A delay time calculation method for calculating a delay time of a semiconductor integrated circuit with consideration for a waveform distortion, the semiconductor integrated circuit including a plurality of instances connected by a plurality of nets, the method comprising:
a first delay time calculation step of calculating a delay time of all the instances and a line delay time of all the nets and signal waveforms at input and output terminals of all the instances;
an instance input signal waveform calculation step of obtaining a distorted input signal waveform which is distorted due to the Miller effect of a delay time calculation subject instance selected from the plurality of instances, the instance input signal waveform calculation step including
inputting a variable input terminal capacitance value of the delay time calculation subject instance which is determined according to the presence/absence of a distortion caused by the Miller effect in an input waveform,
representing the variable input terminal capacitance value as a coupling capacitance between input and output terminals of the delay time calculation subject instance, and
calculating crosstalk using a net connected to the output terminal of the delay time calculation subject instance as an aggressor and a net connected to the input terminal of the delay time calculation subject instance as a victim;
an instance output signal waveform calculation step of obtaining a distorted output signal waveform which is distorted due to the Miller effect of the delay time calculation subject instance, the instance output signal waveform calculation step including
inputting the variable input terminal capacitance value,
representing the variable input terminal capacitance value as a coupling capacitance between the input and output terminals of the delay time calculation subject instance, and
calculating crosstalk using a net connected to the input terminal of the delay time calculation subject instance as an aggressor and a net connected to the output terminal of the delay time calculation subject instance as a victim;
a second delay time calculation step which includes
calculating a delay time of the delay time calculation subject instance based on the distorted input signal waveform and the distorted output signal waveform of the delay time calculation subject instance, and
allowing transfer of the distorted output signal waveform to calculate a delay time of a subsequent instance and a line delay time of a subsequent net.

9. A delay time calculation method for calculating a delay time of a semiconductor integrated circuit with consideration for a waveform distortion using the cell characteristic characterization method of claim 2, the semiconductor integrated circuit including a plurality of instances connected by a plurality of nets, the method comprising:
a slope waveform/bump waveform separation step of separating an input waveform including an superposed input bump waveform, which is input to a delay time calculation subject instance selected from the plurality of instances, into an input slope waveform on which the input bump waveform is not superimposed and the input bump waveform;
a library reference step of referring to the function of the cell characteristic characterization method of claim 2 to obtain an output slope waveform and an output bump waveform of the delay time calculation subject instance which correspond to the input slope waveform and the input bump waveform and obtain as an output waveform of the delay time calculation subject instance an output waveform formed by the output slope waveform and the output bump waveform superimposed thereon; and
if a bump waveform occurs due to an external factor in a subsequent net connected to an output side of the delay time calculation subject instance, a net waveform calculation step of inputting information of the bump waveform and superimposing the bump waveform on an output waveform of the delay time calculation subject instance to calculate an output waveform of the subsequent net.

10. An input waveform calculation method for calculating a distorted input signal waveform of a cell which is distorted due to the Miller effect using the cell characteristic characterization method of claim 1, an input side of the cell being connected to a line, an output side of the cell being connected to a drive load, the method comprising:
an input terminal capacitance calculation step of referring to the function of the cell characteristic characterization method of claim 1 to calculate an effective input terminal capacitance which corresponds to an input waveform of the waveform calculation subject cell which is obtained before the distortion and a value of the drive load; and
a waveform calculation step of calculating an input waveform of the waveform calculation subject cell which is obtained after the distortion based on an output signal waveform of the line connected to the input side of the input waveform calculation subject cell and a load capacitance obtained by adding the capacitance of the line connected to the input side of the waveform calculation subject cell to the calculated effective input terminal capacitance.

11. A delay time calculation method for calculating a delay time of a semiconductor integrated circuit with consideration for a waveform distortion, the semiconductor integrated circuit including a plurality of instances connected by a plurality of nets, the method comprising:
a delay time calculation step which includes
calculating a delay time of all the instances and a line delay time of all the nets, signal waveforms at input and output terminals of all the instances, and an effective input terminal capacitance of all the instances,
inputting a Miller effect-causing condition which includes an input signal waveform and an effective input terminal capacitance,
collating the input signal waveform and the effective input terminal capacitance calculated for each instance with the Miller effect-causing condition,
listing an instance in which the Miller effect is caused in an input signal to output the list as a Miller effect-caused instance list;
a static timing analysis step which includes
assigning the delay time calculated at the delay time calculation step to a netlist to perform a static timing analysis,
determining whether or not a timing of each path satisfies a timing design specification,
if the timing design specification is not satisfied, storing a difference between a timing of the unsatisfactory path and the timing design specification as slack information;
a Miller effect-caused instance extraction step which includes
collating an instance included in a path which is determined not to satisfy the timing design specification at the static timing analysis step with the Miller effect-caused instance list,
if the instance included in the path is included in the Miller effect-caused instance list, calculating a delay variation caused due to the Miller effect of the instance to output the calculated delay variation as a path delay variation report; and
a timing redetermination step which includes
collating the slack information of the path which is determined not to satisfy the timing design specification with the path delay variation report, and
if the timing design specification is satisfied with the delay variation caused due to the Miller effect, redetermining that the path satisfies the timing design specification.

12. A delay time calculation method for calculating a delay time of a semiconductor integrated circuit with consideration for a waveform distortion, the semiconductor integrated circuit including a plurality of instances connected by a plurality of nets, the method comprising:
a static timing analysis step which includes
inputting a netlist, a delay time of the plurality of instances, and a line delay time of the plurality of nets, and
assigning the delay time and the line delay time to the netlist to perform a static timing analysis;
a timing MET determination step of determining whether or not a result of the timing analysis at the static timing analysis step satisfies a timing design specification;
if it is determined at the timing MET determination step that the timing design specification is not satisfied, a circuit modification step of performing a circuit modification including change of the instance size or rearrangement of lines based on layout information for timing correction;
a delay time calculation step which includes
calculating a delay time of all the instances and a line delay time of all the nets after the circuit modification of the circuit modification step, and
after the calculation, returning to the static timing analysis step;
if it is determined at the timing MET determination step that the timing design specification is satisfied, a Miller effect-caused instance extraction step of extracting an instance included in a path in which the Miller effect occurs based on a Miller effect-causing condition but the timing fails to satisfy the timing design specification as a result of the occurrence of the Miller effect; and
a circuit modification method determination step which includes
determining a circuit modification method from a method for modifying the Miller effect-caused instance extracted at the Miller effect-caused instance extraction step and a method for modifying an instance which is a factor that causes the Miller effect, and
returning to the circuit modification step.

13. The delay time calculation method of claim 12, wherein the circuit modification method determination step includes:
a Miller effect-caused instance modification method presentation step of presenting a circuit modification method for changing a cell size of an instance in which the Miller effect is caused to a cell size such that the Miller effect is removed;
a Miller effect-causing factor instance modification method presentation step of presenting a circuit modification method for changing a cell size of an instance which generates a signal waveform that causes the Miller effect to a cell size such that the Miller effect is removed; and
an optimum modification method selection step of comparing the two circuit modification methods presented at the two modification method presentation steps to select therefrom a circuit modification method which causes minimum area damage.
